(19) United States
(12) Patent Application Publication
(10) Pub. No.: US 2025/0055434 A1
(43) Pub. Date: Feb. 13, 2025

(54) METHODS OF FORMING PIEZOELECTRIC LAYERS HAVING ALTERNATING POLARIZATIONS

(71) Applicant: Akoustis, Inc., Huntersville, NC (US)

(72) Inventors: Craig Moe, Penfield, NY (US); Jeffrey M. Leathersich, Rochester, NY (US); Ramakrishna Vetury, Charlotte, NC (US); Abhay Saranswarup Kochhar, Charlotte, NC (US)

(21) Appl. No.: 18/294,809

(22) PCT Filed: Sep. 12, 2022
(86) PCT No.: PCT/US22/76270

§ 371 Date: Feb. 2, 2024

Related U.S. Application Data
(60) Provisional application No. 63/242,666, filed on Sep. 10, 2021.
(60) Provisional application No. 63/363,284, filed on Apr. 20, 2022.

(51) Int. Cl. H03H 3/02; H03H 9/02; H03H 9/17

(52) U.S. Cl. CPC H03H 3/02; H03H 9/02031; H03H 9/173; H03H 9/175; H03H 9/178; H03H 2003/021; H03H 2003/025

(57) ABSTRACT

As disclosed herein, methods of forming piezoelectric layers having alternating polarizations and related bulk acoustic wave filter devices. Pursuant to these embodiments, a method of forming a piezoelectric resonator device can include forming a first material, including metal and nitrogen atoms, using a first process to provide a first piezoelectric layer having the metal and the nitrogen atoms arranged in a first polar orientation, to establish a first polarization for the first piezoelectric layer and forming a second material, including the metal and the nitrogen atoms on the first piezoelectric layer, using a second process to provide a second piezoelectric layer having the metal and the nitrogen atoms arranged in a second polar orientation, to establish a second polarization for the second piezoelectric layer that is opposite of the first polarization.

### CLAIM FOR PRIORITY

The present application claims priority to U.S. Provisional Patent Application Ser. No. 63/242,666 titled METHODS OF FORMING WAFERS FOR PERIODICALLY POLED THICKNESS MODE BULK ACOUSTIC WAVE (PP-XBAW) FILTER CIRCUITS AND FILTER CIRCUITS FORMED USING THE SAME, filed in the U.S.P.T.O. on Sep. 10, 2021 and to U.S. Provisional Patent Application Ser. No. 63/363,284 titled METHODS OF FORMING WAFERS FOR PERIODICALLY POLED THICKNESS MODE BULK ACOUSTIC WAVE (PP-XBAW) FILTER CIRCUITS AND FILTER CIRCUITS FORMED USING THE SAME, filed in the U.S.P.T.O., on Apr. 20, 2022, the entire contents of which are incorporated herein in their entireties.

### STATEMENT OF GOVERNMENT SUPPORT

This invention was made with government support under Agreement No. HR00112290037 awarded by the Defense Advanced Research Projects Agency (DARPA). The government has certain rights in the invention

### FIELD

The inventive concept relates to methods of forming piezoelectric layers and to piezoelectric resonator devices used in, for example, bulk acoustic wave filters devices.

### BACKGROUND

Bandpass filters, multiplexers, and switchplexers in radio frequency (RF) transceivers are used for the coexistence of different wireless standards/technologies. Current mobile devices use many acoustic wave bandpass filters for frequency band selection and interference rejection. With the advent of the 5G, multiple mm-Wave frequency bands are designated for personal communications, further increasing the demand for high performance filters in communication systems. However, conventional SAW and BAW technologies may not efficiently support mm-Wave frequency bands, since the current SAW or BAW resonator technologies may not provide high quality factors (Q) and large electromechanical coupling coefficients (K_{eff}²) above 6 GHz.

### SUMMARY

Embodiments according to the inventive concept can provide methods of forming piezoelectric layers having alternating polarizations and related bulk acoustic wave filter devices. Pursuant to these embodiments, a method of forming a piezoelectric resonator device can include forming a first material, including metal and nitrogen atoms, using a first process to provide a first piezoelectric layer having the metal and the nitrogen atoms arranged in a first polar orientation, to establish a first polarization for the first piezoelectric layer and forming a second material, including the metal and the nitrogen atoms on the first piezoelectric layer, using a second process to provide a second piezoelectric layer having the metal and the nitrogen atoms arranged in a second polar orientation, to establish a second polarization for the second piezoelectric layer that is opposite of the first polarization.

### BRIEF DESCRIPTION OF THE DRAWINGS

FIG. 1 illustrates a 5-layer periodically poled (PP) BAW resonator where the polarization and thickness of each layer can be configured to match the strain field at 18 GHz, resulting in high coupling in some embodiments according to the inventive concept.

FIG. 2 illustrates a COMSOL simulation of the strain profile in a 5-layer PP-XBAW resonator configured to operate with a center frequency of about 18 GHz in some embodiments according to the inventive concept.

FIG. 3 illustrates a simulated wide and narrow band admittance response of the 5-layer PP-XBAW of FIG. 2 showing that the device achieved a kₜ² of about 17.7% at about 18.09 GHz with low spurious response in some embodiments according to the inventive concept.

FIG. 4 illustrates breakdown of 2-18 GHz filter array module area composition by component type in some embodiments according to the inventive concept.

FIG. 5 illustrates a system simulation of a 18 GHz filter with the SP8T and SP4T in some embodiments according to the inventive concept.

FIGS. 6(a)-(c) illustrate lumped element simulation of 8, 12 and 18 GHz filters with 7.5% IBW, respectively with associated quality factor variation in some embodiments according to the inventive concept.

FIG. 7 illustrates a six element mBVD equivalent circuit schematic in some embodiments according to the inventive concept.

FIG. 8 illustrates a BAW resonator operating in a 3^{rd} overtone.

FIG. 9 illustrates measured quality factor of a 5.5 GHz XBAW resonators vs. resonator diameter and the corresponding area-to-perimeter ratio wherein Qₚ is the mechanical quality factor, which degrades when the device size is too small, and Qₛ degrades for larger diameters due to resistive loss in the electrodes which can be offset by thicker metal electrodes in some embodiments according to the inventive concept.

FIG. 10 illustrates a 18 GHz PP-XBAW resonator diameter, volume, and area/perimeter ratio as a function of the number of periodically poled layers therein in some embodiments according to the inventive concept.

FIG. 11 illustrates electromechanical coupling kₜ² of an 18 GHz PP-XBAW vs. electrode thickness showing the top and bottom electrodes each with a thickness of up to 65 nm in some embodiments according to the inventive concept.

FIG. 12 illustrates a 3 layer periodically poled resonator structure grown by MOCVD, sputtering, and MOCVD respectively in some embodiments according to the inventive concept.

FIGS. 13A-13C illustrate a TEM study of MOCVD AlN layer grown on sputtered AlN including a) a TEM cross-section image, b) a high resolution TEM image of the “boxed” region of FIG. 13A showing MOCVD AlN and sputtered AlN with diffraction pattern insets, and c) X-ray diffraction rocking curve of sputtered AlN on Si, MOCVD AlN on Si, and MOCVD AlN on sputtered AlN illustrating the quality of the MOCVD AlN growth on the sputtered AlN in some embodiments according to the inventive concept.

FIG. 14 illustrate methods of forming a 5 layer periodically poled piezoelectric resonator device via alternate deposition processes to provide selective ferroelectric polarization in some embodiments according to the inventive concept.

FIG. 15 illustrates a TEM image showing local epi-templating of AlScN on <111> Al with a native oxide in some embodiments according to the inventive concept.

FIG. 16 illustrates a TEM image showing local epi-templating of AlScN directly on <111> Al in some embodiments according to the inventive concept.

FIG. 17 illustrates TEM image showing local epi-templating of <111> Al directly on AlScN in some embodiments according to the inventive concept.

FIG. 18 illustrates an AFM image of a 500 nm thick Al₆₈Sc₃₂N film grown directly on Si showing the surface as free of AOGs resulting in an low surface roughness of about 0.74 nm wherein the stress can be controlled to be slightly tensile at about 875 MPa in some embodiments according to the inventive concept.

FIG. 19 illustrates a measured admittance plot of a high frequency resonator device fabricated from Al₆₈Sc₃₂N material, demonstrating about 17.4% coupling, Op, of about 781, and a FOM of about 137 in some embodiments according to the inventive concept.

FIG. 20 illustrates ferroelectric remnant polarization vs. electric field for about 45 nm thick Al₆₈Sc₃₂N measured using PUND in some embodiments according to the inventive concept.

FIG. 21 illustrates polarization vs. switching cycle at a field of about 6.3 MV/cm for Al₆₈Sc₃₂N showing 8700 full polarization switching cycles in some embodiments according to the inventive concept.

FIG. 22 illustrates a 5-layer periodic coupling (PC) BAW resonator wherein the coupling of each layer is maximized or minimized to match the strain field of the acoustic wave at the specified frequency of the resonator operation in some embodiments according to the inventive concept.

FIG. 23 illustrates a FEM simulation showing the admittance response and strain profile through the thickness (inset B) of a 5-layer, Al₆₈Sc₃₂N/Al (about 232 nm/about 175 nm) PC-XBAW resonator demonstrating kₜ²>11% in some embodiments according to the inventive concept.

FIG. 24 illustrates a ladder filter network with 5s5p topology in some embodiments according to the inventive concept.

FIG. 25 illustrates a BAW resonator subject to traditional frequency scaling including related trade-offs.

FIG. 26 illustrates a BAW resonator subject to ‘n’th overtone scaling.

FIG. 27 illustrates a 5 layer Periodically Polarized (PP) BAW resonator subject to scaling in some embodiments according to the inventive concept.

FIG. 28 illustrates a 18 GHz PP-XBAW resonator device operation as a function of diameter, volume, and area/perimeter ratio vs number of PP layers in some embodiments according to the inventive concept.

FIG. 29 illustrates a TEM image of Al/AlScN/Al showing epitaxial interfaces in the insets in some embodiments according to the inventive concept.

FIG. 30 illustrates a ferroelectric P-E loop measured in an about 20 nm thick Al₆₈Sc₃₂N film in some embodiments according to the inventive concept.

FIG. 31 illustrates ferroelectric P-E loops measured in an about 200 nm thick Al₆₈Sc₃₂N film in some embodiments according to the inventive concept.

FIG. 32 is an FOM Plot illustrating kₜ² as a function of frequency of operation of AlScN resonators as various concentrations of Sc in some embodiments according to the inventive concept.

FIGS. 33A-33B are graphs illustrating performance of BAW resonator devices having Al₆₈Sc₃₂N piezoelectric layers formed to about 485 and 380 nm as a function of frequency in some embodiments according to the inventive concept.

FIGS. 34A-34C through FIGS. 49A-49C are diagrams illustrating various cross-sectional views of a crystal acoustic resonator device including a plurality of periodically poled piezoelectric layers and methods of forming the same using a transfer process with a sacrificial layer in some embodiments according to the inventive concept.

FIGS. 50A-50C through FIGS. 62A-62C are diagrams illustrating various cross-sectional views of a crystal acoustic resonator device including a plurality of periodically poled piezoelectric layers and methods of forming the same using a transfer process with a multilayer mirror structure in some embodiments according to the inventive concept.

FIG. 63 illustrates a filter including a switched filter bank including HOPS resonators arranged in an electrical ladder network in some embodiments according to the inventive concept.

FIGS. 64A-64C illustrate a plan view of a capacitor including an Al₆₈Sc₃₂N metal polar layer, a cross-sectional view of the capacitor, and a preliminary structure used to form the capacitor via KOH, respectively, in some embodiments according to the inventive concept.

FIG. 65 illustrates performance modeling using a periodically poled BAW Mason model configuration for a piezoelectric layer in some embodiments according to the inventive concept.

FIG. 66 is a graph illustrating performance of the capacitor of FIG. 64 in some embodiments according to the inventive concept.

### DETAILED DESCRIPTION OF EMBODIMENTS ACCORDING TO THE INVENTIVE CONCEPT

According to embodiments of the present invention, techniques generally related to electronic devices are provided. More particularly, the present invention provides techniques related to a method of manufacture and structure for bulk acoustic wave resonator devices, single crystal resonator devices, single crystal filter and resonator devices, and the like. Merely by way of example, the invention has been applied to a single crystal resonator device for a communication device, mobile device, computing device, among others.

As appreciated by the present inventors, in some For BAW resonators the area taken by the resonator is given according to

$$area ∝ \frac{1}{{freq}^{2}}$$

and the volume occupied by the resonator is given by

$$volume ∝ \frac{1}{{freq}^{3}} .$$

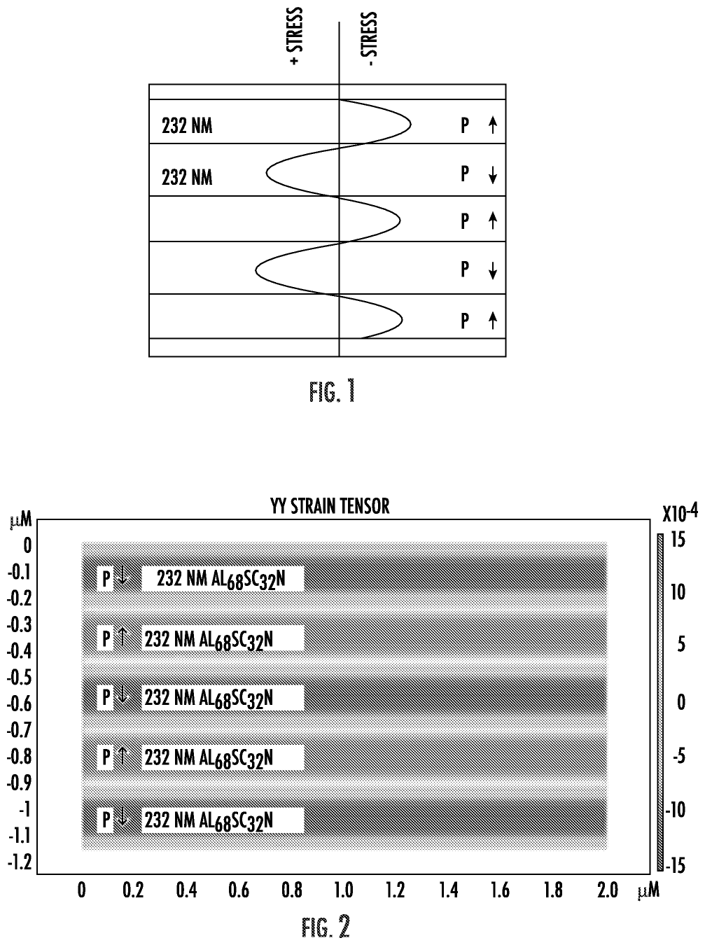

When scaling BAW resonators to X and Ku bands, however, the physics governing device operation may result in unacceptably low quality factors, as acoustic energy can leak out the side of the much smaller resonators, and unacceptably low power handing, as the low volume of frequency scaled resonators may increase the acoustic power density. As appreciated by the present inventors, fixed frequency filters can be formed using periodically poled (PP) thickness mode bulk acoustic wave resonators, sometimes referred to herein as PP-XBAW, as depicted in FIG. 1 which schematically illustrates a 5 layer piezoelectric stack having periodically poled layers that provide opposing ferroelectric polarizations and where the thickness of each layer can be configured to match the strain field generated at 18 GHz. This configuration can result in high coupling in some embodiments according to the inventive concept. In particular, the 5 layers in the piezoelectric stack can have a specified thickness, such as about 232 nm as shown, to operate the BAW resonator having a center-frequency of about 18 GHz.

In some embodiments according to the present invention, PP-XBAW resonator architecture can address the traditional limits in BAW resonator frequency scaling discussed above, which can enable the resonator area and volume to be configured independently of the operating frequency, such as at 18 GHz. In some embodiments according to the present invention, the PP-XBAW resonator can provide these properties by operating in an overtone mode through the device thickness as shown in FIG. 1. In some embodiments according to the present invention, the PP-XBAW utilizes periodic poling of the stack of piezoelectric layer to match the sign (positive or negative) of the piezoelectric coefficient with the stress/strain distribution through the device thickness, as shown in FIG. 1, allowing all the overtones through the thickness to add constructively to contribute to the overall response. Using this approach, the PP-XBAW can enable the full kₜ² of the underlying piezoelectric material, independent of the number of layers utilized to form the resonator.

FIG. 2 illustrates a COMSOL simulation of the strain profile in a 5-layer PP-XBAW resonator configured to operate with a center frequency of about 18 GHz in some embodiments according to the inventive concept. As shown in FIG. 2, the simulated piezoelectric stack of layers can be formed of Al₆₈Sc₃₂N that are about 232 nm thick.

FIG. 3 shows the admittance response simulated using COMSOL finite element modeling (FEM), of the 18 GHz, 5-Layer PP-XBAW resonator stack formed from periodically poled Al₆₈Sc₃₂N shown in FIG. 2. FIG. 3 shows a clean response, with a weak spur far from the desired resonance, and a high kₜ² of about 17.7%. In some embodiments according to the inventive concept, a coupling was demonstrated in Al₆₈Sc₃₂N at about 4.4 GHz as illustrated in FIG. 19. The high coupling of AlScN materials can enable large fractional bandwidth and low insertion loss filters. In some embodiments according to the present invention, devices formed as described herein can provide the filter performance shown in Table 1.

Metrics Color Table

| | Embodiment | Embodiment | Embodiment |
|---|---|---|---|
| | 1 | 2 | 3 |
| Filter Metrics | | | |
| Center Frequency (GHz) | 18 | 8, 12, 18 | 8, 12, 18 |
| Max. Insertion Loss (dB) | <2.8 | 1.9 | 1.9 |
| Instantaneous | 5% | 7.5% | 7.5% |
| Bandwidth (%) | | | |
| Out-of-Band | >25 | 32 | 32 |
| Rejection (dB) | | | |
| Selectivity (dBc) | >17 | 21 | 23 |
| In-band Power | >20 | 30 | >30 |
| Handling (dBm) | | | |
| In-band/Out-of- | 30/60 | 40/70 | 50/80 |
| band IIP3 (dBm) | | | |
| Maximum Frequency | N/A | N/A | 0.15 |
| Variability (%) | | | |
| Filter Area | N/A | 0.6 | 0.57 |
| (mm²) (<69/30) | | | |
| Filter Power | 0 | 0 | 0 |
| Consumption (mW) | | | |
| Filter Temperature | −45 | −40 | −40 |
| Coefficient of | | | |
| Frequency (ppm/° C.) | | | |
| Filter Vibration | N/A | <1 | <1 |
| Sensitivity (ppb/G) | | | |
| PP-XBAW Resonator | | | |
| Properties | | | |
| Thickness (nm) of a | 231 | 231, 350, 525 | 231, 350, 525 |
| Single Poled Layer | | | |
| for 18, 12, 8 GHz | | | |
| # of Periodically Poled | 5 | 5, 3, 2 | 5, 3, 2 |
| Layers for 18, 12, 8 GHz | | | |
| Al Electrode | 50 | 50, 75, 112 | 50, 75, 112 |
| Thickness (nm) | | | |
| for 18, 12, 8 GHz | | | |
| Min. Electromechanical | >11 | 15 | 15 |
| Coupling, kₜ² (%) | | | |
| Min. Quality Factor (Q) | 450 | 450 | 450 |
| Max. Power Density | 0.5 | 0.55 | 0.59 |
| (mW/μm³) | | | |

In some embodiments according to the present invention, aspects of the disclosed methods of forming PP-BAW resonators and filters can provide acceptable filter loss across the instantaneous bandwidth at high frequency, high power handling at high frequency in a small footprint, and uniformity at high frequency. In some embodiments according to the present invention, the PP-BAW devices and methods can utilize fixed frequency filters.

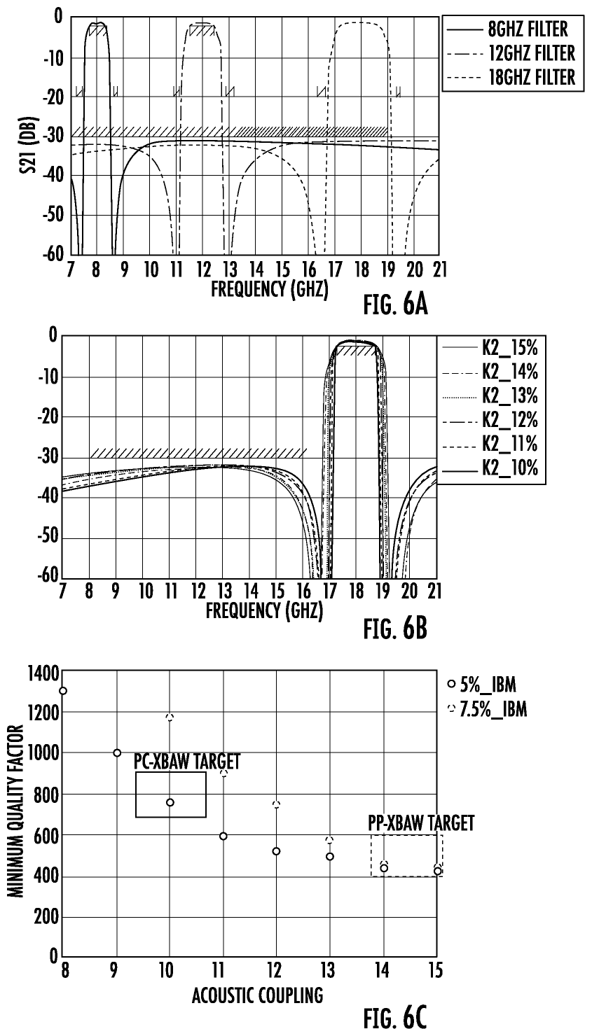

As appreciated by the present inventors, scaling to a 2-18 GHz filter array can be enabled using switches in the system architecture as described below. In some embodiments according to the inventive concept, a periodically poled piezoelectric material and resonator design can decouple BAW resonator thickness, area, and volume from the frequency of operation. The PP-XBAW approach allows resonator scaling to 18 GHz while independently tailoring the volume and area-to-perimeter ratio to achieve the desired power handling and quality factor (Q). In some embodiments according to the inventive concept, the PP-XBAW resonator can allow independent design for both center frequency and volume (i.e,. power density). The PP-XBAW materials (i.e. number of layers) and resonators/filters can be configured to set the power density below 0.625 mW/μm³, resulting in power handling in excess of +30 dBm. The ability of the PP-XBAW resonator be independently designed for center frequency, area (or area-to-perimeter ratio) and impedance can address filter insertion loss metrics and provide a high quality factor as shown, for example, in FIG. 6.

In a BAW resonator, the energy stored is determined by the device area while the energy lost to the anchors is determined by the perimeter, making the area-to-perimeter ratio a key parameter that can limit the maximum achievable Q factor. The disclosed PP-XBAW materials (i.e., number of layers) and resonators/filters can be configured to set the resonator area >1455 μm² (corresponding area-to-perimeter ratio to >10.8), a value that can result in Q factors in excess of 400 for 50 $2 some BAW resonators at 5.5 GHZ. At Ku-band, the PP-XBAW resonator can allow for thicker metal electrodes when compared to traditional BAW resonators. Proper metal electrode thickness can enable high device Q-factor and power handling.

In some embodiments according to the inventive concept, use of high coupling aluminum scandium nitride (AlScN) materials can be used to provide 3.5 GHz filters in Al₇₂Sc₂₈N with 6.2% fractional bandwidth and power handling >+40 dBm and BAW resonators in Al₆₈Sc₃₂N with kt2=17.5% and Qp=781 at 4.4 GHZ, as shown for example in FIG. 19.

As can be seen in FIG. 6, a minimum kt2 of about 8% can provide factional bandwidth performance using miniature acoustic resonators. Higher coupling relaxes the required quality factor, enables wider bandwidth filters, and results in fewer filters required to cover the 2-18 GHz frequency band. In some embodiments according to the present invention high coupling materials can provide 7.5% fractional bandwidth filters, resulting in a Q factor of 450, a reduced number (30) of fixed frequency filters, and a low area of 0.6 mm2.

In some embodiments according to the inventive concept filters and resonators realized using a wafer transfer process as described in U.S. patent application Ser. No. 15/784,919 titled “PIEZOELECTRIC ACOUSTIC RESONATOR MANUFACTURED WITH PIEZOELECTRIC THIN FILM TRANSFER PROCESS,” filed Oct. 16, 2017 which issued as U.S. Pat. No. 10,355,659 on Jul. 16, 2019. It will be understood that the wafer transfer process described in U.S. patent application Ser. No. 15/784,919 is sometimes referred to herein by the term “XBAW.”

The wafer transfer process described therein can allow precision transfer and two-sided MEMS processing of a resonator device including a resonator device wherein the piezoelectric layer is a periodically poled stack of piezoelectric layer layers as described herein. In some embodiments according to the inventive concept, the transfer process can provide advanced frequency trimming capabilities for uniformity at the wafer level of 343 ppm (or 0.03%). In some embodiments according to the present invention, a thickness-based frequency trimming can provide operation to 18 GHz resulting in a frequency uniformity of 0.12%,

In some embodiments according to the inventive concept, the use of BAW resonators can result in small size, high coupling and Q, and low spurious responses over wide bandwidths that have not been demonstrated in other acoustic resonator technologies, such as Lamb wave and cross-sectional Lame’ mode resonators. As disclosed herein, a PP-XBAW resonator can have a low spurious response as shown in FIG. 3, and has been demonstrated to provide low spurious BAW resonators as shown in IG. 19. The low spurious response of XBAW resonators can enable the performance described herein, as any spurs near the filter passband will cause excessive ripple violating the insertion loss metric.

In some embodiments according to the inventive concept, multiple fabrication approaches can be used to optimize the periodically poled material including the alternating formation of epitaxial and sputtered AlScN layered stacks, selective electrical ferroelectric poling of AlScN layers and a periodic coupling material.

As described herein, a 2 GHz to 18 GHz filter architecture can be adopted to provide the performance disclosed. In some embodiments, the disclosed filters may not have tuning capability so RF switching will be provided by the final system filter having 7.5% instantaneous bandwidth. This can reduce the complexity of the final system and allow implementation with approximately 30 filters, in some embodiments. The integration of 30 filters in a switchable filter bank can be achieved with a single pole, eight throw (SP8T) switch cascaded at each port with a single pole, four throw (SP4T) switch and one of the 30 filters at each port. The physical dimensions of the system are disclosed considering approximate device die size to achieve the desired performance, current wafer level packaging capabilities and module assembly design rules.

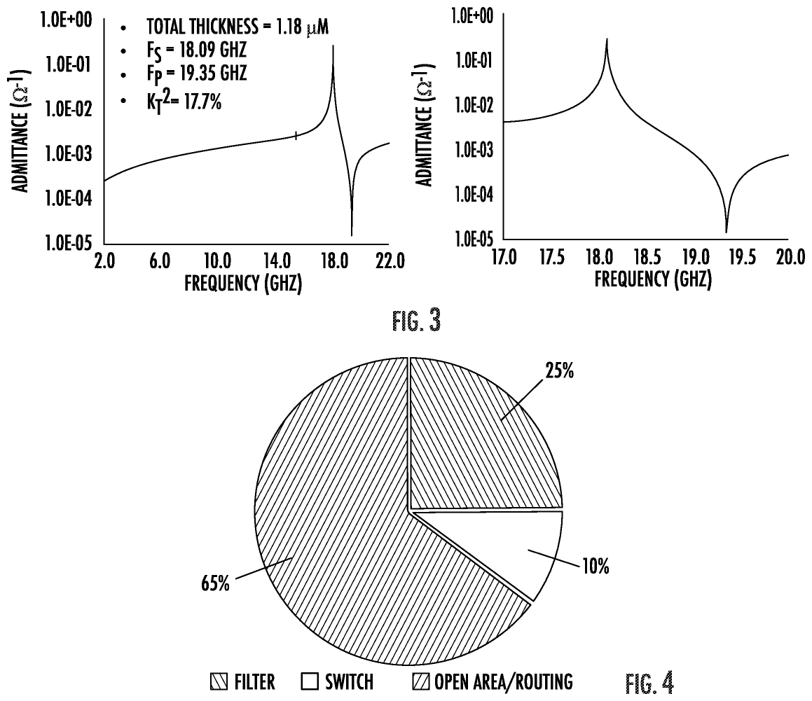

Due to the high frequency operation, the components on a die can be very small in comparison to die routing (vias and bumps) by the wafer level process. Therefore, the pin out from the die can be used to make an accurate estimate of the chip size. An estimation of filter die size is approximately 0.75 mm×0.75 mm, SP4T switch die size of 0.8 mm×0.8 mm, and SP8T switch die size of 1.4 mm×1.4 mm. In some embodiments of the inventive concept, the estimated final system size would be about 8.25 mm×8.25 mm, where breakdown of components by module composition is shown in FIG. 4.

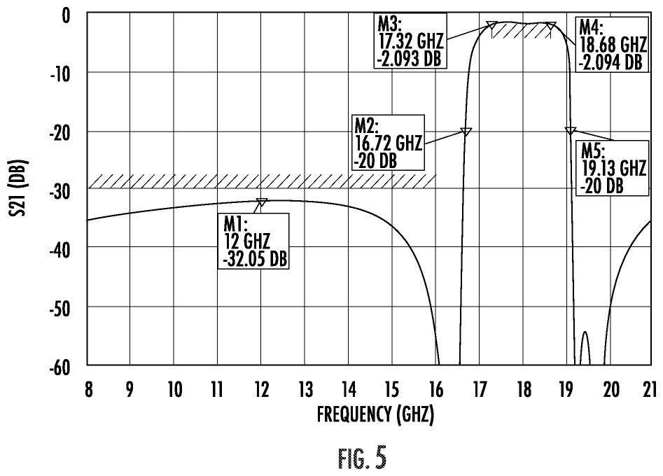

In some embodiments according to the invention, phase-change material RF switches can be used in the filter architecture that have demonstrated FOM of about 6 fs and a cutoff frequency >25 THz. The switches can have an on resistance (Ron) of about 2.3Ω and off capacitance (Coff) of about 2.7 fF. Using this switch model, a lumped element representation of the SP4T and SP8T switches was constructed and simulated with a lumped element 18 GHz 7.5% IBW filter having the performance illustrated in FIG. 5 and FIG. 6. This resulted in the 18 GHz switch path having a total insertion loss (switches+filter) better than −2.1 dB. The selectivity specification remained >20 dB and out of band rejection >30 dB. The simulated performance is shown in FIG. 5.

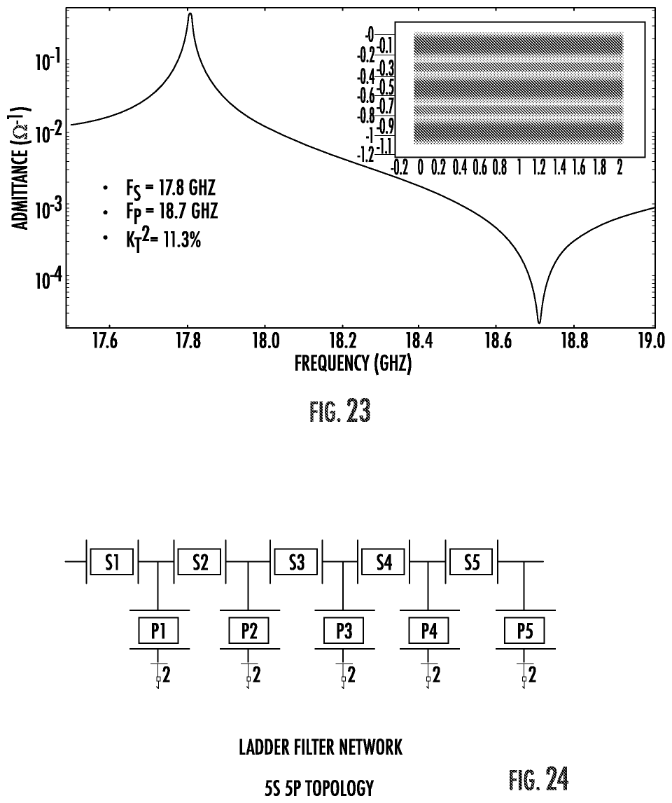

As disclosed herein, operation of BAW filters can be expanded to X and Ku bands for dynamic element level filtering in digital phased arrays. FIG. 6 shows a lumped element linear simulated band pass filter response that meets or exceeds the small signal specifications shown in Table 1 at 8, 12, and 18 GHz assuming an instantaneous bandwidth (IBW) of about 7.5%. This filter was realized using a half ladder topology including five stages (5s5p) as shown in FIG. 24 in some embodiments according to the inventive concept. The BAW resonators in the filter ladder network of FIG. 14 had an acoustic coupling (kt2) of 15% and quality factor (Q) of 450, performance which may provide operation up to the 18 GHz range.

Acoustic coupling can be achievable in the range from about 10% to about 15%. As the coupling increases the quality factor may decrease. FIG. 6(b) shows a plot of the 18 GHz filter with different resonator models that contain acoustic coupling ranging from about 10% to about 15% and the quality factor adjusted to the minimum value for each coupling that allows the filter to meet these specifications with a 7.5% IBW. FIG. 6(c) shows the various resonator models from FIG. 6(b) along with the minimum quality factor. An additional curve is added to this plot to show how the model minimum Q changes when the filter targets the 5% IBW specification.

As appreciated by the present inventors, an estimation of large signal performance can be determined by considering the performance of existing 6 GHz WiFi filters. In some embodiments, an 18 GHz filter can be provided with performance comparable to the demonstrated 6 GHz filter as the 5th overtone can be utilized for the 18 GHz filter compared to the fundamental tone for the 6 GHz. The 6 GHz filter demonstrated resonator power density volumes that exceed 0.59 mW/μm³ and power handling up to 30 dBm (1 W). The nonlinear performance of this part demonstrated an in-band IIP3 of 63 dBm.

The transfer process described herein can provide several features that enhance operation and produce high quality figures of merit while at the same time suppressing undesired modes and generating clear resonant responses. One such feature is the configuration of the resonator anchor or periphery in some embodiments according to the inventive concept. In some embodiments, lateral modes can be suppressed, and the leakage of acoustic energy can be reduced to enhance the quality factor.

Filter design can utilize a circuit model of the electro-mechanical operation of the resonator for fast synthesis of the design topology. In some embodiments according to the invention, a six-element modified Butterworth Van Dyke (mBVD) can be utilized. A schematic of the mBVD model is shown in FIG. 7. The model includes three resistive elements that can affect the quality factor. The series resistance (Rₛ) is correlated to the Q at resonance, the static branch resistance (R₀) correlates to Q at anti-resonance, and the mechanical resistance (Rₘ) correlates strongly to max Q. The static capacitance (C₀) represents the parallel plate capacitance of the resonator away from resonance. The mechanical inductance (Lₘ) and capacitance (Cₘ) set the model resonance and anti-resonance frequencies, respectively.

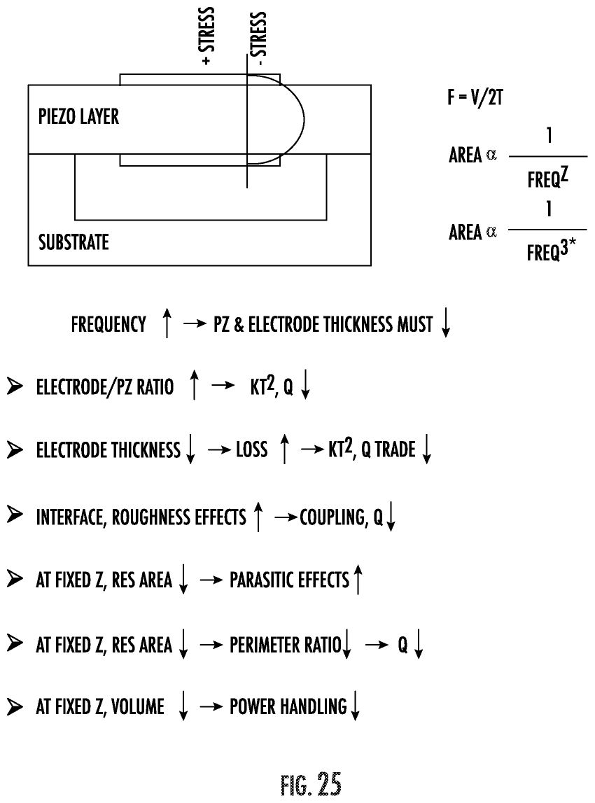

BAW resonators have demonstrated vibration sensitivities of about 0.1 part-per-billion (ppb) per gravity (G), orders of magnitude below what is required for a 5% IBW filter. In some embodiments according to the inventive concept, BAW resonator filters can be scaled to X and Ku bands. Referring to FIG. 25, one approach to scaling the frequency of BAW resonators is given by the following relationship between piezoelectric layer thickness (t) and acoustic velocity (v):

$$f = v / 2 t$$

Therefore, scaling can involve reducing the thickness of the piezoelectric film to achieve higher frequency of operation. As appreciated by the present inventors scaling in this manner to the X- and Ku-band frequencies, however, may present challenges that may adversely affect device performance. For example, as the piezoelectric film is thinned, the electrodes become a larger part of the device volume. The strain stored in the electrodes does not contribute to device coupling as they do not possess piezoelectric properties. The larger influence of the metal on the resonator stack can lead to a damping effect that reduces the Q of the device.

The damping effect can be mitigated by reducing the thickness of the electrodes, but this may lead to the metals becoming more electrically lossy and therefore reducing the Q factor. Surface roughness of the thin piezoelectric films can lead to scattering effects that act as another loss mechanism for the resonator. As the frequency of operation increases, so may the effect of the scattering losses. Furthermore, as the piezoelectric stack and the electrodes are thinned the interface between the various layers may become a significant portion of the device which may lead to a reduction in kt2.

To maintain a constant device impedance, the area (A) of the resonator can be scaled down as the inverse square of the operating frequency. The resulting parasitic routing capacitance can lead to a reduction of effective kt2. As the area-to-perimeter ratio becomes smaller, a significant amount of energy may leak from the periphery of the resonator and degrade the mechanical Q. The reduction in both the area and the piezoelectric film thickness can degrade the power handling of the resonator as the power density limit of the material may be exceeded.

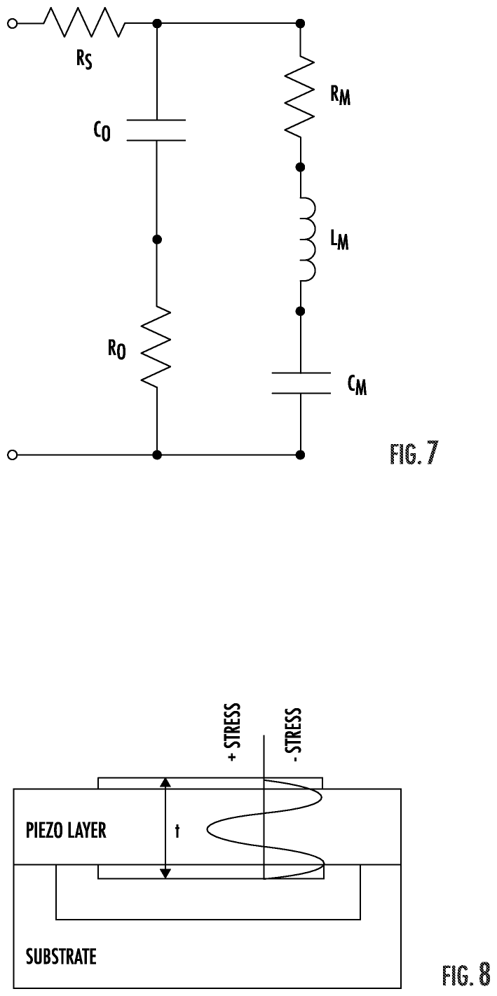

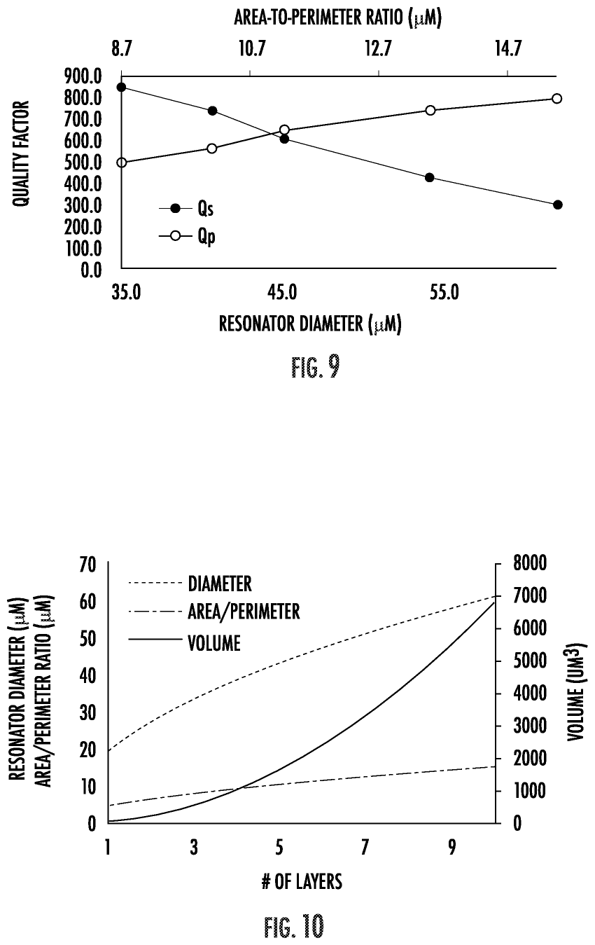

As appreciated by the present inventors, a different frequency scaling approach can be used for BAW resonators to operate at X- and Ku-bands. Referring to FIG. 26 as an illustration of overtone (n) operation, the operating frequency of the device is set by n*f0, where f0 is the fundamental tone. In this approach, a reduction in the effective kt2 of the device may occur as shown by FIG. 8 and FIG. 26, where the standing wave in ⅓ of the device thickness is in tension (positive stress) while ⅔ of the device thickness is in compression (negative stress). Since the material has a single polarization, the response of ⅔ of the film cancels itself, leaving only ⅓ of the film contributing to coupling. The result is that the effective kt² is degraded by 1/n².

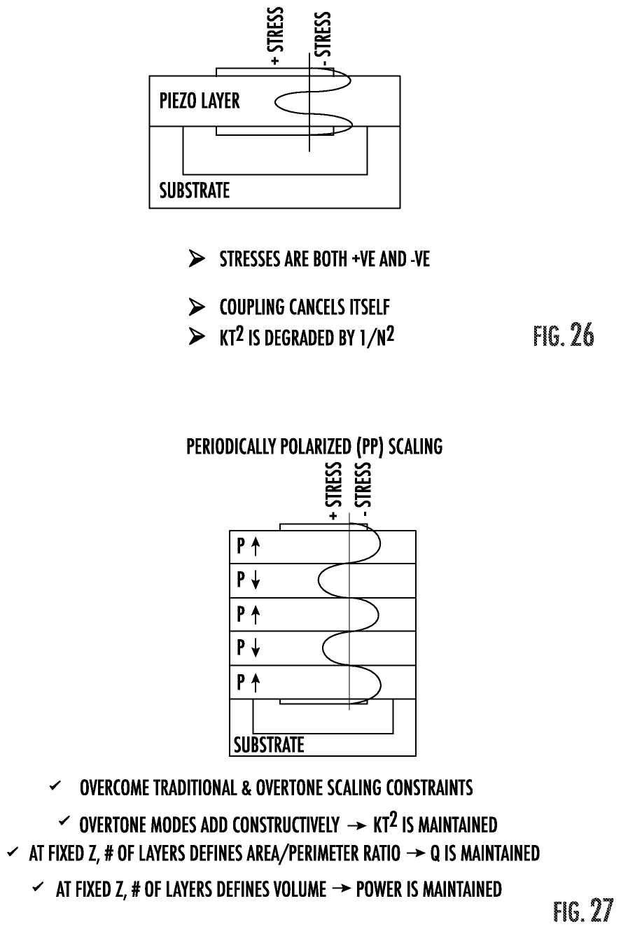

In some embodiments according to the present invention, scaling the resonant frequency of BAW resonators can be provided without requiring a reduction in the overall device thickness or area, as depicted for a 5-layer PP-XBAW in FIG. 2 and FIG. 27. Unlike the traditional overtoned resonator in FIG. 8, the PP-XBAW selectively configures the polarization through the thickness of the material to match the stress/strain profile at the desired overtone of operation. As such, the product of the polarization and strain adds constructively through the film thickness, maintaining high effective kt² independent of the number of overtones/layers. In other words, in some embodiments according to the present invention, the direction of the polarization of the layers can be configured as a function of stress/strain profile at the desired overtone of operation such that coupling results in an addition rather than a subtraction due to cancellation generated in the overtoned mode operation.

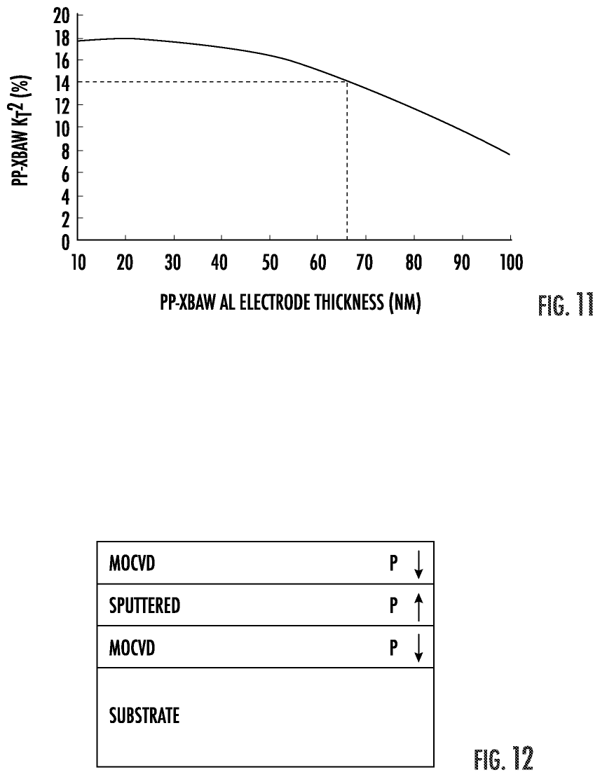

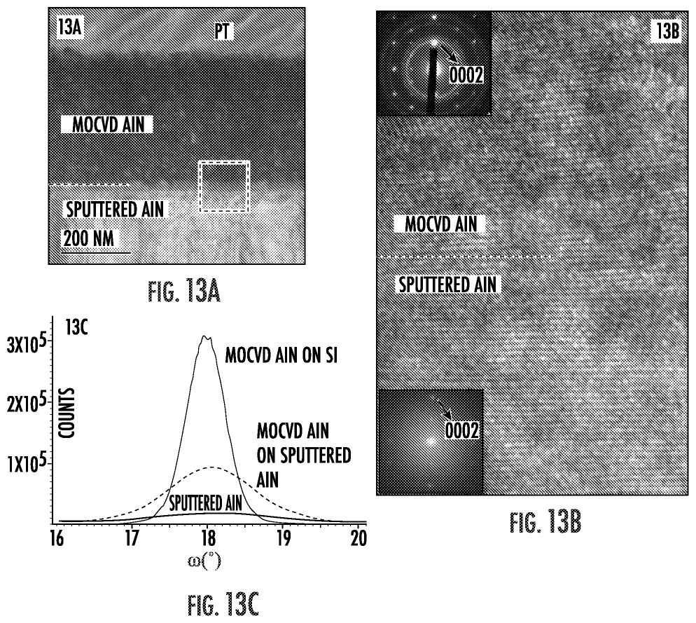

A COMSOL Finite Element Model (FEM) for a 5-layer PP-BAW operating at 18 GHz was performed. The device utilized 10 nm thick Al electrodes, about 232 nm thick Al68Sc32N layers, and was simulated. FIG. 2 shows the simulated strain profile through the thickness at the resonant frequency of about 18.09 GHz, demonstrating that the periodic polarization in the material has been designed to match the strain/stress profile. The admittance of this PP-BAW resonator vs. frequency is shown in FIG. 3, demonstrating kt²=17.7%. Even when increasing the electrode thickness to 65 nm, the kt² remains above 14% as shown in FIG. 11, which depicts FEM results for the kt² of the PP-XBAW vs. electrode thickness.

As appreciated by the present inventors, this demonstrates the ability of the PP-XBAW to allow much thicker electrodes at high frequency, which can enable improved power handling and Q factor metrics. The wideband admittance response from 2-22 GHz shows only a single, strong resonance mode, allowing wideband operation without distortion due to in-band spurs or unintended filter responses in other frequency bands.

To evaluate the impact of the PP-BAW approach on the resonator area and volume, consider Al₆₈Sc₃₂N with a relative permittivity of 16 and a sound velocity of 8393 m/s resulting in a layer thickness tl=232 nm for 18 GHz operation. FIG. 10 shows the PP-XBAW diameter,

$${Z}_{off} = \frac{1}{2 π f {C}_{s}} = 50$$

periodically poled layers in the design is increased from 1 to 10, where Cs is the shunt capacitance of the PP-BAW resonator. Z_{off}=50Ω is a common impedance utilized in ladder filter design. For a standard single layer BAW the resonator at 18 GHZ, the diameter is 19 μm, resulting in an extremely small volume of 68 μm³ and leading to very low power handling. Furthermore, the low area-to-perimeter ratio of 4.8 μm can result in low quality factor, Qₚ, due to high anchor losses.

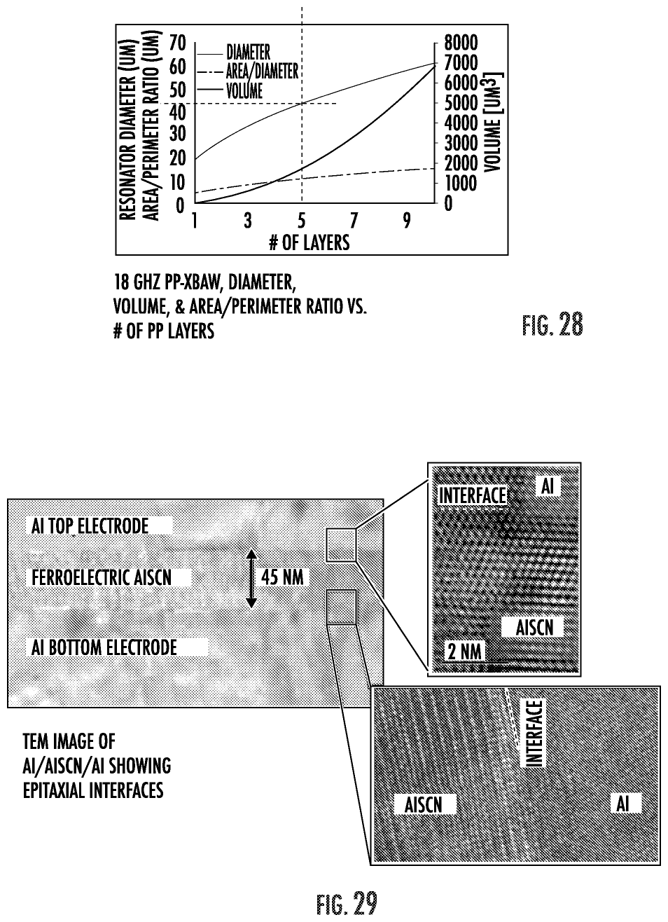

By contrast and referring to FIG. 28, a 5-layer design, such as that shown in FIG. 2 or FIG. 27, has an increased device diameter of 43 μm leading to a 2.2 times greater area-to-perimeter ratio, increasing the anchor loss limited quality factor. As shown in FIG. 9, XBAW resonators at 5.5 GHz with diameters between 35 and 56 μm achieved Q factors >400 in accordance with some embodiments of the inventive concept. Increasing the number of layers can also increase the resonator volume, to 1696 μm³ for a 5-layer PP-XBAW, resulting in a 25 times decrease in the device power density compared to a traditional single layer BAW.

The XBAW wafer transfer process has demonstrated that resonators with a volume of 500 μm³ can survive power levels exceeding +30 dBm at 5.7 GHz under continuous wave operation. Additionally, 5.8 GHz XBAW bandpass filters, with a max resonator volume of 1600 μm³, have been developed for the WiFi market capable of operating at +30 dBm across the entire passband when driven with a modulated signal of 802.11ax, 80 MHz channel width, 1024 QAM, and 50% duty cycle. Thus, filters including 5-layer 18 GHz PP-BAW resonators, each occupying a volume of 1696 μm³, can exceed both the +30 dBm power handling spec and the Q factors of 400 to meet the filter selectivity and insertion loss in some embodiments according to the inventive concept.

The PP-XBAW architecture can also allow an increase in the number of layers to further increase power handling and Qp factor. Using the PP-BAW approach, the direct relationships between the device operating frequency, total thickness, electrode thickness, power handling, quality factor, and electromechanical coupling of past approaches can be addressed. Through engineering of the piezoelectric material stack, resonators operating at 18 GHz that simultaneously possess optimal electromechanical coupling, high Q factor (from increased device area-to-perimeter ratio) and high linearity (from increased device volume) can be provided.

In some embodiments according to the inventive concept, the layers in the PP-XBAW resonators can be deposited using methods that are configured to provide a respective polar orientation for atoms, such as metal and nitrogen atoms included materials such as AlScN, such that piezoelectric layers formed have a particular polarization as formed (i.e., in-situ). For example, one deposition method can provide a piezoelectric layer with a first polarization whereas another deposition method can provide another piezoelectric layer (with that same piezoelectric material) with a second polarization that is opposite to the first polarization. Accordingly, the piezoelectric layers deposited using different methods can have different (e.g., opposing) polar orientations when formed (i.e. in-situ) such that those differently formed piezoelectric layers have the different polar orientations. Accordingly, a piezoelectric stack in some embodiments according to the inventive concept, can provide the periodically poled piezoelectric layers without the need to be configured using applied voltages across the piezoelectric layers via electrodes.

It will be understood that the term “opposite” can include embodiments where piezoelectric layers are grown so that the resulting respective polarizations of the different piezoelectric layers are different from one another so that the respective polarizations tend to oppose one another. Furthermore, the term “opposite” can include embodiments where piezoelectric layers are grown so that the respective polarizations of the different piezoelectric layers are directly opposite to one another.

In some embodiments according to the present invention, a disclosed periodically poled piezoelectric layer stacks is schematically depicted in FIG. 12. According to FIG. 12, MOCVD grown AlScN layer was formed to a thickness equal to about ½ of the acoustic wavelength. As appreciated by the present inventors, MOCVD layers can be formed to have a metal polar orientation as discussed in, for example, J. Ligl et al., “Metalorganic chemical vapor deposition of AlScN/GaN heterostructures,” Journal of Applied Physics 127, 195704 (2020). Accordingly, an MOCVD process can be used to deposit a piezoelectric material (including metal and nitrogen atoms, such as AlScN) that has atoms arranged in a first polar orientation (i.e., metal polar) as-formed so that the resulting or established polarization (P) of the piezoelectric material layer(s) can be provided in-situ as shown in FIG. 12.

It will be understood that, as used herein, the term “polar orientation,” can be used to describe where metal and nitrogen atoms included in, for example, a piezoelectric material are arranged in a piezoelectric layer to have a particular polar orientation. For example, in some embodiments, metal and nitrogen atoms can be arranged in a deposited material to have different polar orientations, depending on the method of deposition used to form the piezoelectric layer. Furthermore, in some embodiments according to the inventive concept, the metal and nitrogen atoms can be arranged in the deposited material to have a polar orientation to establish a polarization for the piezoelectric layer in which the metal and nitrogen atoms are included.

In some embodiments according to the inventive concept, the piezoelectric layer is exposed to ambient, which can develop charges on the surface of the piezoelectric layer that can terminate the polarization so that the material at the surface becomes charge neutral. Note, this will not degrade the piezoelectricity but will allow an oppositely polarized material to be grown on the surface of the first layer.

In some embodiments according to the inventive concept, another AlScN layer can be sputtered, for example, using PVD, onto the surface of the MOCVD layer, with a thickness equal to about ½ of the acoustic wavelength. Sputter deposited AlScN materials are grown so that the Al and N atoms are nitrogen polar and will therefore establish a polarization for the AlScN layer that is opposite to that of the MOCVD grown layer described above.

In some embodiments according to the inventive concept, a third layer AlScN grown on the second sputtered layer using MOCVD. A MOCVD growth is performed to deposit the next periodic layer in the stack. The process can be repeated until the total desired number of layers are realized. Although FIG. 12 shows three periodically poled piezoelectric layers, it will be understood that a PP piezoelectric stack of layers can be formed to include more layers by repeating the alternating deposition of the MOCVD and sputter layers described above, in addition to exposing the MOCVD layer to ambient to neutralize the charge of the MOCVD layer before sputtering the next piezoelectric layer onto the MOCVD layer. Furthermore, in some embodiments according to the inventive concept, materials other the AlScN, such as a piezoelectric material that includes a metal and a nitrogen (such as AlN), can be configured to have a metal polar or nitrogen polar orientation as-formed such that those piezoelectric layers have different polarizations in-situ. Still further, in some embodiments according to the inventive concept, the order of the layers shown in FIG. 12 can be changed. For example, in some embodiments according to the inventive concept, the sputtered layer can be formed on the substrate, followed by the layer formed via MOCVD. It will be understood that the sputtered and MOCVD layers can be formed to have the polarizations shown in either sequence of formation.

In still further embodiments according to the inventive concept, processes other than MOCVD and sputtering can be used to form the piezoelectric layers described above. For example, in some embodiments according to the inventive concept, any process that provides for epitaxial growth can be used to form the MOCVD piezoelectric layer described above, such as MBE, and other CVD processes. In some embodiments according to the inventive concept, any process that provides for non-ordered growth can be used to from the sputtered piezoelectric layer described above. Still further, in some embodiments according to the inventive concept, the materials used to form the epi and sputtered layers can be ferroelectric.

The quality of the MOCVD and sputtered materials can be assessed via X-Ray diffraction (XRD), atomic force microscopy (AFM), and electron diffraction patterns acquired using Transmission Electron Microscopy (TEM). To access the polarization achieved in each layer TEM can be used to image the location of the N atoms with respect to the metal atoms. An alternative method is to directly determine the polarity of the stacked layers through the use of nanoscale electron diffraction methods. In particular, the “4D-Scanning Transmission Electron Microscopy” (4D-STEM) technique allows a capture of the convergent beam electron diffraction (CBED) pattern at each point of the sample as the electron beam undergoes raster scanning to form the image. CBED patterns can directly determine the polarity by comparing the patterns with appropriate computational modelling.

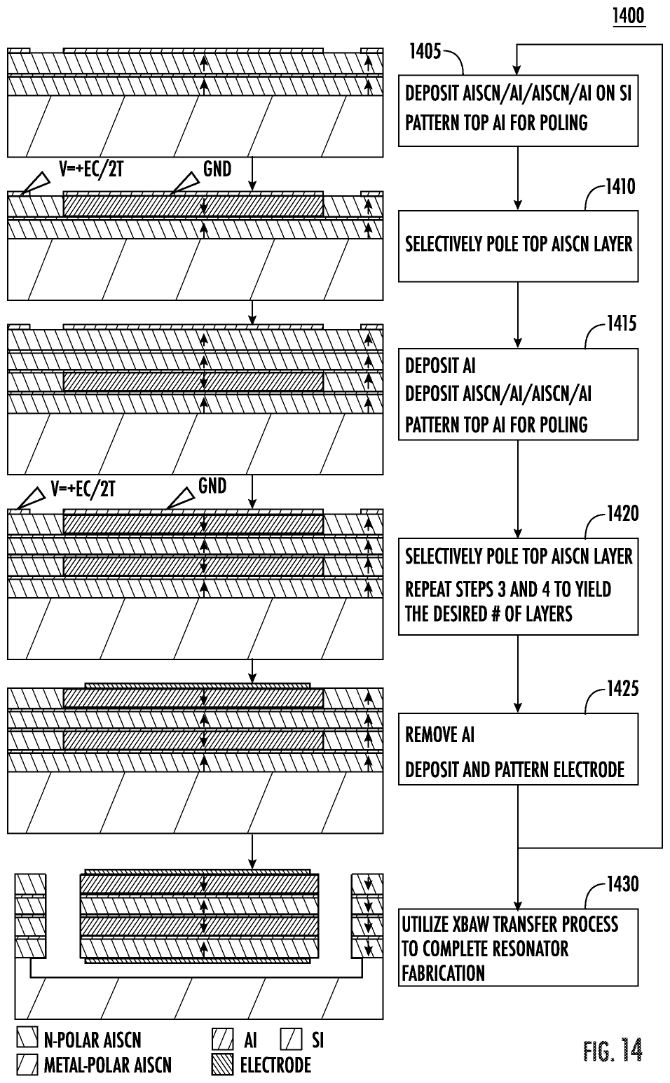

An MOCVD AlN material was grown on a sputtered AlN material. A TEM cross section image of the layer stack is shown in FIG. 13A. The interface between the MOCVD and sputtered layers is clearly visible, with the sputtered layer exhibiting polycrystalline growth with orientation along the c-axis. High resolution TEM images of the MOCVD and sputtered layers and the interface between the two regions are shown in FIG. 13B. Local epitaxial growth of the MOCVD AlN on the sputtered AlN is clearly observable via the ordered atomic planes of the AlN crystal.

To further assess the quality of the MOCVD layer, isolated electron diffraction patterns were measured for both the MOCVD and sputtered AlN layers, as shown in the insets in FIG. 13B, confirming the strong 0002 orientation in both materials. The high quality MOCVD growth directly on sputtered AlN is further confirmed in FIG. 13C, which shows an X-ray diffraction (XRD) rocking curve for sputtered AlN on Si, MOCVD AlN on Si, and MOCVD AlN grown on sputtered AlN. The MOCVD AlN grown on the sputtered AlN exhibits a narrower rocking curve than the sputtered AlN alone. These results for AlN illustrate that this growth technique can be utilized for the proposed MOCVD/Sputtered AlScN layer stacks.

In some embodiments according to the inventive concept, a periodically poled piezoelectric stack of 4 layers can be formed and processed according to the wafer transfer process described herein as shown in FIG. 14. According to FIG. 14, a first AlScN layer is grown directly on Si to have a first ferroelectric polarization, as described herein below. Without breaking vacuum, a first Al layer is deposited on the first AlScN layer. A second AlScN layer is formed on the first Al layer to have the first ferroelectric polarization. A second Al layer is formed on the second AlScN layer and the second Al is patterned to form poling electrodes that are laterally spaced apart on the second AlScN layer as shown (block 1405). As deposited the AlScN films will be nitrogen polar, as shown in FIG. 14.

In some embodiments according to the inventive concept, each of the AlScN layers shown in FIG. 14 can be formed to a thickness that is about equal to ½ the wavelength and all Al layers can be formed to a thickness that is less than 20 nm.

A poling voltage is applied to the poling electrodes to switch the ferroelectric polarization of the second AlScN layer to the metal polar state via the top electrode connections and floating first Al layer as shown in FIG. 14 (block 1410).

The poling electrodes are stripped off the second AlScN layer using HF and the second Al layer is re-formed on the second AlScN layer. A third AlScN layer is formed on the second Al layer to have the first ferroelectric polarization and a third Al layer is formed on the third AlScN layer. A fourth AlScN layer is formed on the third Al layer to have the first ferroelectric polarization. A fourth Al layer is formed on the fourth AlScN layer and patterned to form poling electrodes on the fourth AlScN layer (block 1415).

A poling voltage is applied to the poling electrodes to switch the ferroelectric polarization of the fourth AlScN layer to the metal polar state via the top electrode connections and the floating third Al layer as shown (block 1420). The poling electrodes are stripped off the fourth AlScN layer using HF and the fourth Al layer is re-formed on the fourth AlScN layer (block 1425). In some embodiments according to the inventive concept, the AlScN layers ca be formed by sputtering, using for example PVD, although it will be understood that other processes may be used to form nitrogen polar layers as-formed. In some embodiments according to the inventive concept, MOVCD or other processes can be used to form epitaxial piezoelectric layers having metal polar layers as-formed, selected ones of which may be switched to nitrogen polar using the poling electrodes as described herein. The process described in blocks 1405 to 1425 can be repeated to provide a periodically poled piezoelectric stack having a particular number of layers.

In still further embodiments according to the inventive concept, the periodically poled piezoelectric stack formed can be provided to the wafer transfer process described herein to provide a resonator device as shown (block 1430).

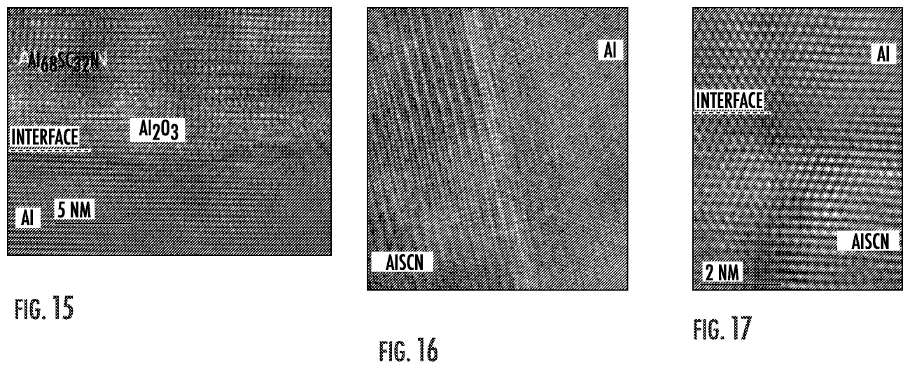

Local epitaxial growth of AlScN via sputtering, using for example PVD, on both <111> Al with native oxide has been demonstrated as shown in FIG. 15 and directly on <111> Al as shown in FIG. 16. Local epitaxial growth of thin <111> Al on AlScN directly at the AlScN/Al interface has also been demonstrated as shown in FIG. 17.

Referring to FIG. 29, AlScN materials on Al electrodes, have been demonstrated to have the ferroelectric and piezoelectric device performance illustrated. FIG. 29 further illustrates a magnified image of the interface region, also shown in FIG. 16, between the bottom electrode and the ferroelectric AlScN layer of the multilayer stack shown in FIG. 29. FIG. 29 also shows a magnified image of the interface region, as also shown in FIG. 17, between the top electrode and the ferroelectric AlScN layer of the multilayer stack shown in FIG. 29.

As show in FIG. 29 the thickness of the ferroelectric AlScN layer is 45 nm although other thicknesses are contemplated including, for example, thicknesses in a range of about 20 nm to about 200 nm. This process can also achieve different layer configurations on the same wafer. For example, periodically poled stacks tailored for 4, 8, 12, and 16 GHz PP-XBAW resonators.

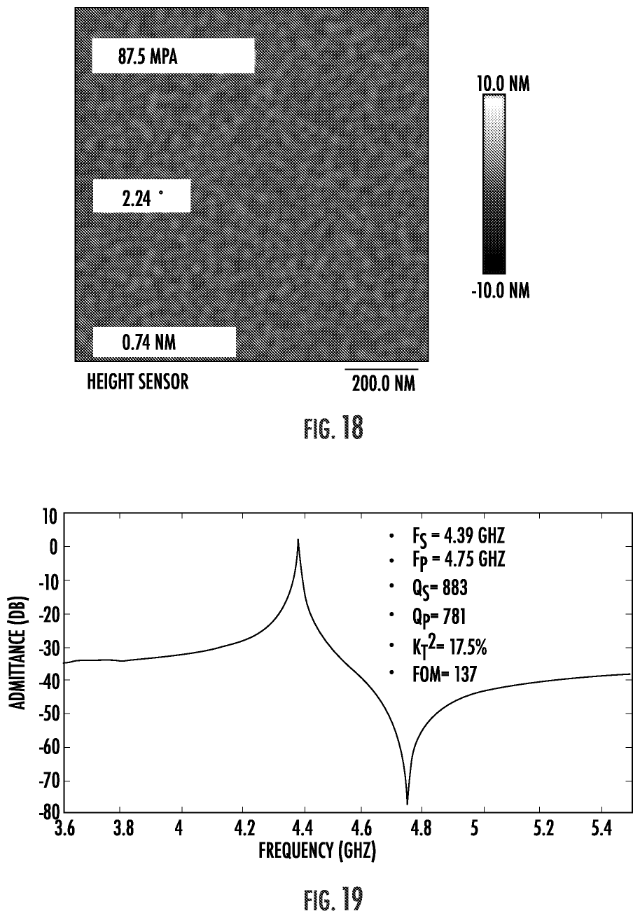

Piezoelectric resonator and ferroelectric performance has been demonstrated using Al₆₈Sc₃₂N. PP-XBAW resonators at 18 GHz with the desired Q factors utilize high quality materials with high c-axis orientation, low surface roughness, that are free of anomalously oriented grains (AOGs), and with stress controlled within the +300 MPa range required by the XBAW process in some embodiments according to the inventive concept. FIG. 18 shows an atomic force microscopy image of a 500 nm thick Al₆₈Sc₃₂N material grown directly on Si. A process gas flow of 25 sccm N2 and 0 sccm Ar is utilized to achieve a slightly tensile stress of 87.5 MPa and to suppress AOGs, resulting in an ultralow surface roughness of 0.74 nm to ensure low scattering loss at Ku-band.

The X-ray diffraction full-width-half-maximum (FWHM) in an ω-scan for this film is 2.2°, showing the high c-axis orientation of the material. Achieving low stress in AlScN films with high Sc doping, which are usually highly compressive, can be provided by using higher sputtering process pressures that typically result in aggressive growth of AOGs. As appreciated by the present inventors, it has been demonstrated that even higher quality materials, free of AOGs, can be provided by depositing on Al. Numerous 400 nm and 600 nm thick Al₆₈Sc₃₂N materials grown on Si, with properties (XRD FWHM, stress, roughness, no AOGs) similar to that in FIG. 18 have been deposited, formed and used in the XBAW fabrication process to form resonators. FIG. 19 shows the admittance plot of a BAW resonator with Z_{off}=1/2πfCₛ=55Ω realized from 400 nm thick Al₆₈Sc₃₂N materials.

Table 2 compares the performance of the devices formed according to the present invention to high coupling, high frequency BAW resonators reported in the literature. As shown in Table 2 the quality (Sc doping, roughness, XRD) of the presently disclosed materials and fabrication process results in the high coupling and Q factor.

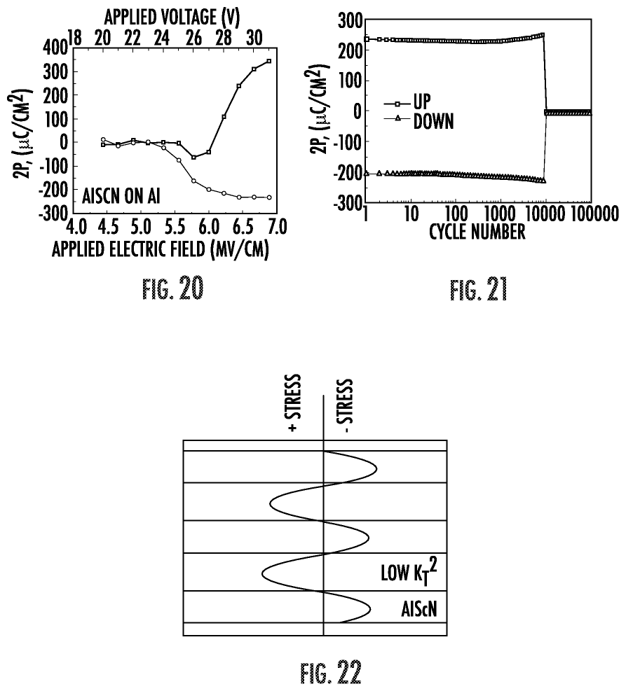

In addition to the piezoelectric performance detailed above, embodiments according to the present invention can allow highly alloyed (28-36%) AlScN to be used. FIG. 20 shows the measured remnant polarization vs. electric field and voltage for a 45 nm thick Al₆₈Sc₃₂N material deposited on Al electrodes measured using the Positive Up Negative Down (PUND) technique. The large and saturated measured remnant polarization ensures the sign of the piezoelectric coefficient is fully inverted. FIG. 21 shows the remnant polarization vs. switching cycle at a switching field of 6.3 MV/cm, demonstrating 8700 switching cycles, well beyond the single write cycle needed for fabricating the PP-XBAW using the approach depicted in FIG. 14. Ferroelectric switching in layers ranging from 20 nm to 100 nm in thickness, and at Sc alloying levels ranging from 28% to 36% has also been demonstrated.

TABLE 2
Comparison of high coupling, high frequency AlScN BAW resonators
to embodiments according to the present invention.

| Sc | fₛ | fₚ | kₜ² | | | thickness | | |
|---|---|---|---|---|---|---|---|---|
| (%) | (GHz) | (GHz) | (%) | Qₛ | Qₚ | (nm) | FOM | Source |
| 20 | 4.09 | 4.29 | 11.0 | — | 210 | 400 | 23 | Bogner |
| 30 | 2.93 | 3.17 | 17.2 | 328.5 | — | 900 | 57 | Wang |
| 32 | 4.39 | 4.75 | 17.5 | 883 | 781 | 400 | 137 | Inventive |
| | | | | | | | | Example |
| | | | | | | | | Emobodiment |

In some embodiments according to the inventive concept, a periodic coupling overtoned BAW (PC-XBAW) can be provided as shown in FIG. 22. According to FIG. 22, a stack of high and low (or zero) kt2 materials is thickness matched to the stress field of the acoustic standing wave. Whereas embodiments described herein in reference to PP-XBAW embodiments are cable of accessing the full coupling of the piezoelectric material, the PC-XBAW can achieve about ½ of the intrinsic material coupling (for kt2low=0) for a large number of layers. Given the kt² values demonstrated for Al₆₈Sc₃₂N of >17.5% this yields a kt²>8.75%. An odd layer stack, such as that shown in FIG. 22, can achieve slightly higher coupling due to larger volume fraction of high coupling material. In some embodiments according to the inventive concept PC-BAW performance can be achieved by ensuring that the low kt² materials have very low coupling and are either conductive or have high relative permittivity compared to AlScN, so that most of the applied electric field falls across the AlScN.

According to FIG. 22, AlScN/Al layers can be grown, where Al can provide a low kt² material, relative to the piezoelectric material in the stack, such as the AlScN. In some embodiments according to the inventive concept, the relatively low kt² material can be a metal layer and can include, for example, W, Pt, Mo, and TiN, which can be sputtered, using for example PVD, onto the piezoelectric layer (such as the AlScN layer). An admittance plot of a PC-XBAW constructed from a 5-layer stack of Al₆₈Sc₃₂N/Al (232 nm/175 nm) generated using COMSOL FEM is shown in FIG. 23, with the inset showing the simulated and optimized strain profile through the device thickness. The results show a kt² of 11.3%. When compared to the PP-XBAW, the lower coupling of the PC-XBAW can result in the filter fractional bandwidth being reduced to 5% as shown in FIG. 6. In some embodiments according to the inventive concept, high modulus conductive nitride materials, e.g. TiN, or high modulus metals, such as W can provide relatively high Q factors.

PP-XBAW resonators have been configured at 18, 12, and 8 GHz to simultaneously meet the impedance, kt², Q factor, and power handling required to achieve the filter performance with the designs presented in Table 3. In particular, the number of layers in the PP-XBAW resonators are designed for an area-to-perimeter ratio between 10-15 to ensure high quality factor as shown in FIG. 9, and the volume is kept above 1600 μm³ to match the power density of some resonators when driven at +30 dBm. It is clear from the table that the PP-XBAW allows the decoupling of the volume and area of a BAW resonator from the impedance and operating frequency, thus enabling scaling to X and Ku bands.

TABLE 3
PP-XBAW Resonator Design Parameters to Achieve the Q and Power Handling Required by the Filters.

| | | | Thickness | | | | | | |
|---|---|---|---|---|---|---|---|---|---|
| | | | of a | Al | Total | | Area-to- | | Power |
| | Off | # of | Single | Electrode | Resonator | Electrode | Perimeter | | Density |
| Frequency | Impedance | Poled | Layer | Thickness | Thickness | Diameter | Ratio | Volume | @ +30 dBm |
| (GHz) | (Ω) | Layers | (nm) | (nm) | (nm) | (μm) | (μm) | (μm³) | (mW/μm³) |
| 8 | 50 | 2 | 525 | 112 | 1274 | 61 | 15.3 | 3723 | 0.27 |
| 12 | 50 | 3 | 350 | 75 | 1200 | 50 | 12.5 | 2356 | 0.42 |
| 18 | 50 | 5 | 231 | 50 | 1255 | 43 | 10.8 | 1822 | 0.55 |

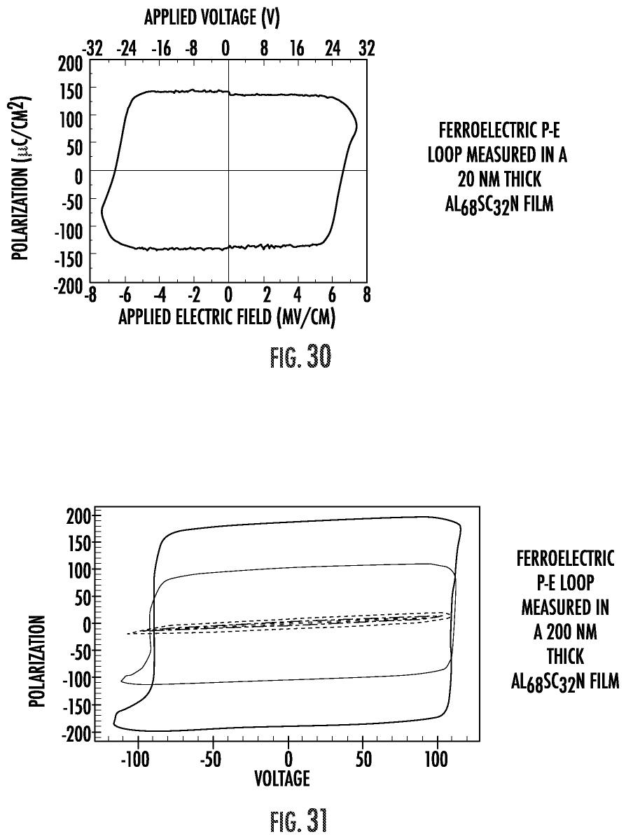

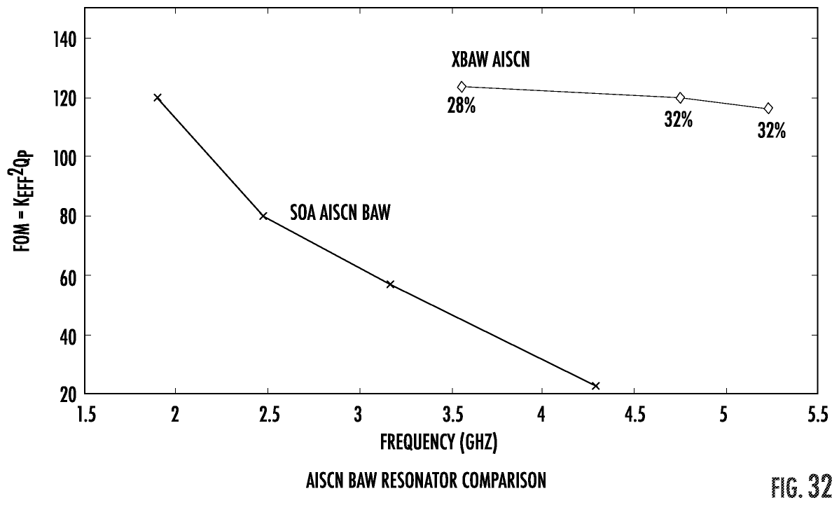

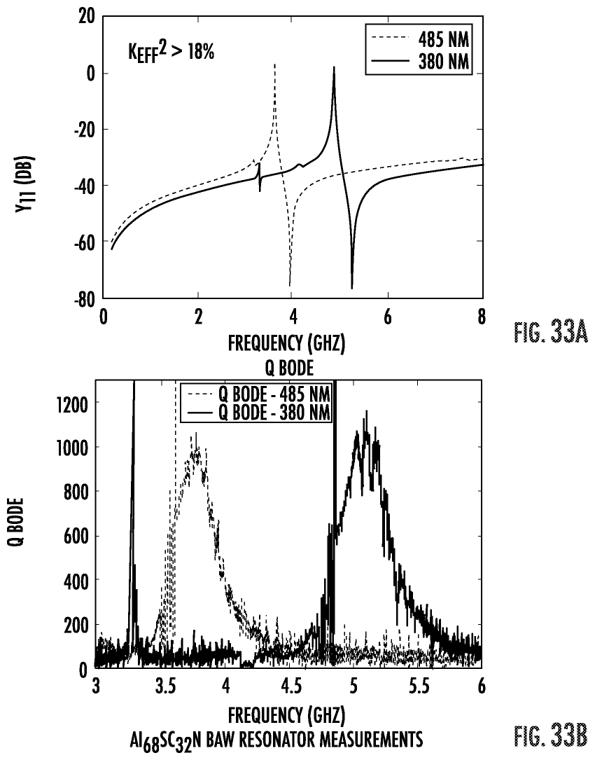

Referring to FIGS. 30 through 33B, performance of the AlScN BAW resonators discussed herein is exceptional as is evidenced by the P-E plots shown in FIGS. 30 and 31, the FOM plot shown in FIG. 32, and the plots shown in FIGS. 33A and 33B. Still referring to FIG. 32, performance of the AlScN BAW resonators described herein stand in contrast to conventional AlScN BAW resonators, which indicates that FOM decreases as frequency increases.

As further appreciated by the present inventors, Embodiments according to the inventive concept including the periodically poled as-formed devices (shown in FIGS. 1, 2, and 27), electrode poled devices (shown in FIG. 14), and periodically coupled devices (shown in FIG. 22) can be combined to provide devices with periodically poled piezoelectric stacks in resonators and filters discussed herein. In particular, in some example embodiments according to the inventive concept, resonators can be provided by combining two or more of these devices. For example, a resonator stack can include a periodically poled portion and an electrically poled portion. Additionally, in some example embodiments, filters can include resonators of different types, periodically poled, electrode poled, or periodically coupled devices, depending on the application of the filter.

Although some example embodiments discussed herein have included a 5 layer PP-BAW, the inventors recognize that the specific number of layers can vary depending on application and performance criteria. For example, material layers can include from 2 to about 20 layers, and more preferably, from 2 to about 5 layers, and even more preferably 4 layers or 5 layers. In some example embodiments, a layer can include contiguous materials that have the same direction of polarization. In this sense, a layer can include materials with different concentrations of scandium (Sc) and aluminum (Al), for example, a super lattice, which would be considered as one layer.

As appreciated by the present inventors the percentage of scandium in the piezo layer(s) can vary while still producing acceptable results. For example, the percentage of scandium can range from 0% to 50%, and more preferably from greater than 0% to about 40%, and even more preferable from about 20% to about 40%. The percentage of scandium (Sc) in the piezo layer(s) can have an effect on the material stack configuration. For example, when the percentage of scandium is 0% a periodically poled material stack is typically implemented. Electrode metals can include aluminum (Al), aluminum-copper (AlCu), Molybdenum (Mo), titanium (Ti), tungsten (W), platinum (Pt), ruthenium (Ru), iridium (Ir), titanium-tungsten (TiW), titanium nitride (TiN), or any alloy combinations of these materials.

In still further aspects according to the inventive concept, the inventors have developed high-band operation via periodic structures (also referred to as “HOPS”) to reduce the likelihood of occurrence of one or more of the problems described herein.

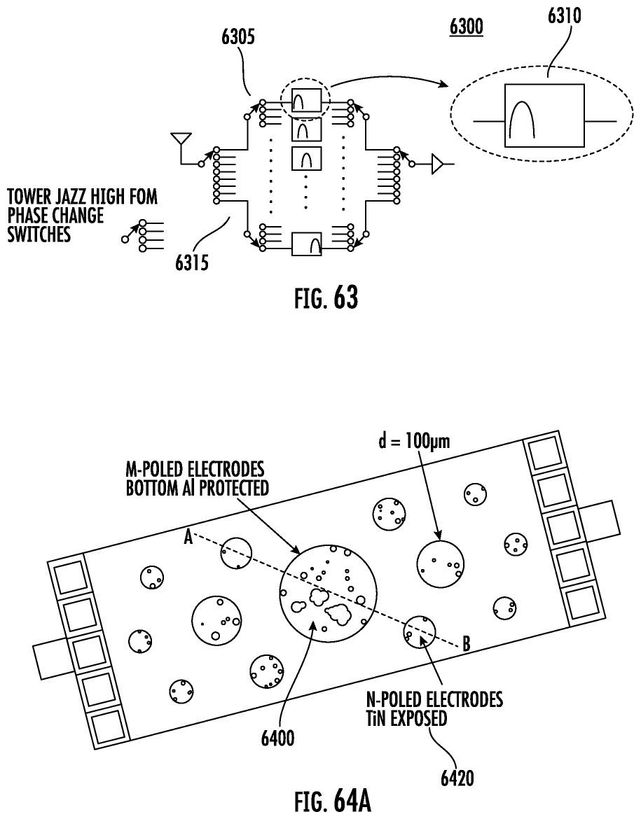

Referring to FIG. 63, HOPS can be used in filter configurations to improve filter performance. As shown in FIG. 63, in some embodiments according to the inventive concept, a filter 6300 can include a switched filter bank 6305 including HOPS resonators 6310 arranged in an electrical ladder network or other configuration. In some example embodiments, the HOPS resonator 6310 can be a periodically poled piezoelectric resonator device including, for example, a stack of five layers of piezoelectric material having alternating polarizations as-formed. As further described herein, HOPS resonators 6310 can also include electrode poled, periodically coupled, or combinations of the three resonator types. As further shown in FIG. 63, Tower Jazz phase change SOTA FOM switches 6315 can be used in conjunction with the filters and resonators 6310 disclosed herein.

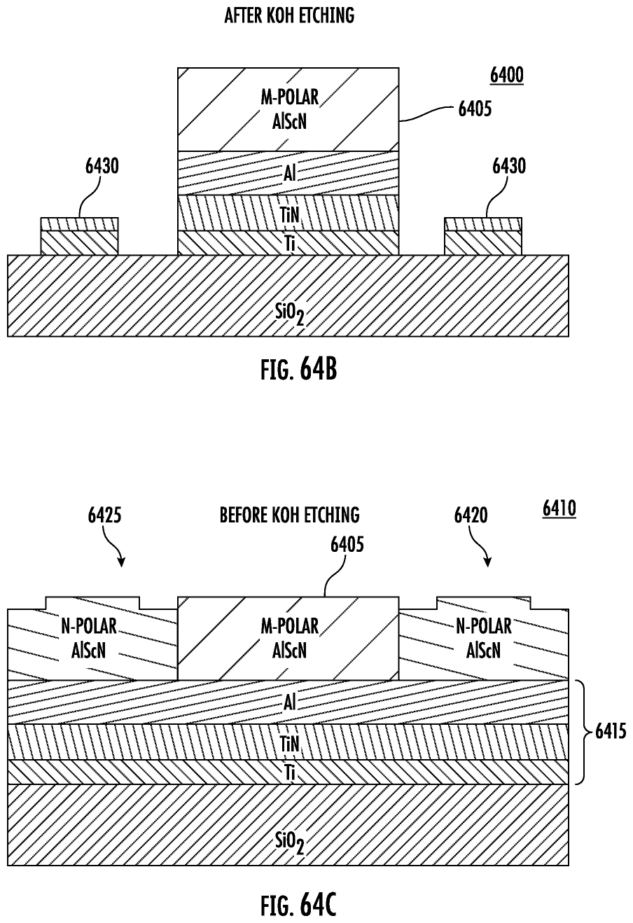

FIGS. 64A-64C illustrate a capacitor 6400 including an Al₆₈Sc₃₂N metal polar layer 6405 in some embodiments according to the inventive concept. In particular, FIG. 64A is a plan view of the capacitor 6400 whereas FIG. 64B is a cross-sectional view of the capacitor 6400 taken along line A-B. FIG. 64C illustrates a preliminary structure used to form the capacitor 6400 via KOH etching in some embodiments according to the inventive concept.

As shown in FIG. 64C, a stack of Ti/TiN/Al can be formed on SiO₂ and a nitrogen polar Al₆₈Sc₃₂N layer can be formed on the stack to form the structure 6410. A portion of the Al₆₈Sc₃₂N layer in the structure 6410 can be electrically poled to reverse the ferroelectric polarization of a portion of the Al₆₈Sc₃₂N layer to form a metal polar portion 6405 of the Al₆₈Sc₃₂N layer. The Al₆₈Sc₃₂N layer is etched to remove the nitrogen polar Al₆₈Sc₃₂N portions of the Al₆₈Sc₃₂N layer whereas the metal polar portion 6405 of the Al₆₈Sc₃₂N layer remains.

As further shown in FIG. 64A, portions of the Ti/TiN/Al stack beneath the nitrogen polar portions of the Al₆₈Sc₃₂N layer are removed to form N-poled TiN electrodes 6420.

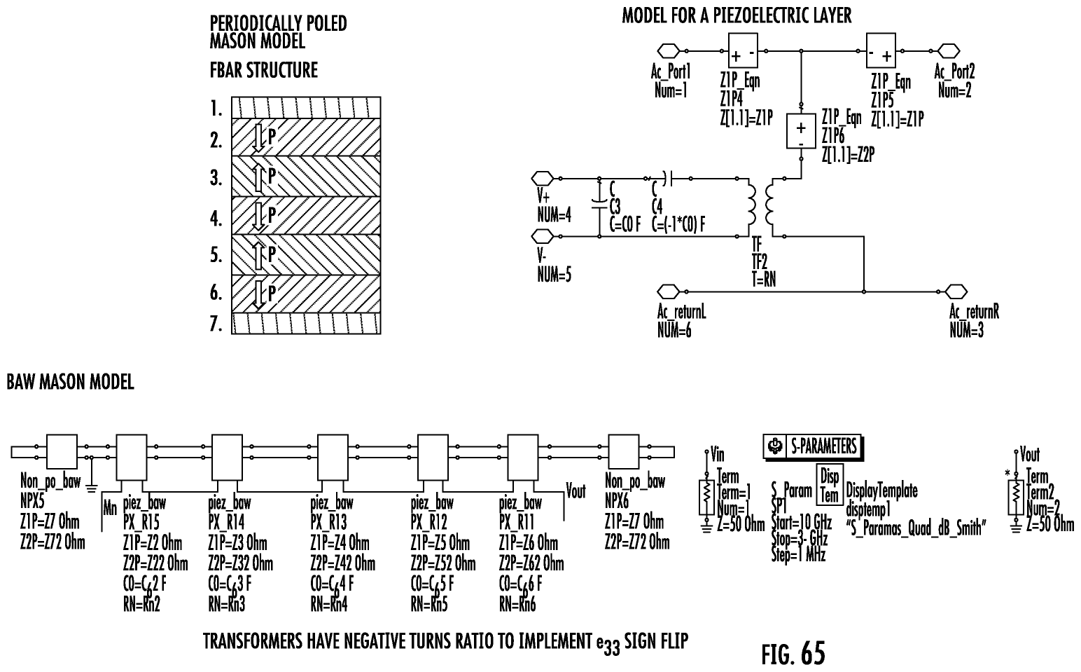

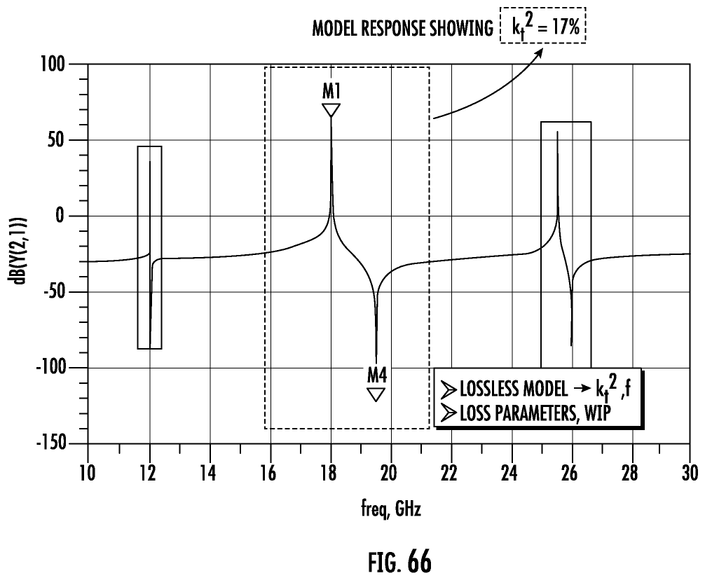

Performance modeling including, for example, the periodically poled Mason modeling configuration for a piezoelectric layer shown in FIG. 65 indicates acceptable performance, as shown in FIG. 66, while reducing the likelihood of occurrence of at least one of the problems described herein.

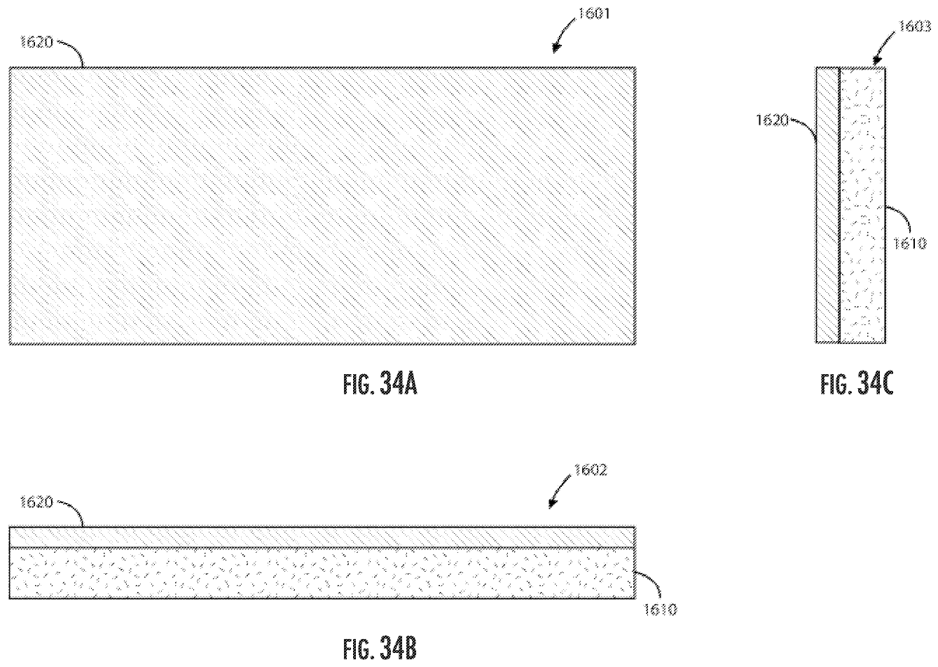

FIGS. 34A-34C through FIGS. 49A-49C illustrate methods of fabricating an acoustic resonator device including a plurality of periodically poled piezoelectric layers, as described herein, using a transfer structure with a sacrificial layer. In these figure series described below, the “A” figures show simplified diagrams illustrating top cross-sectional views of crystal resonator devices according to various embodiments of the present invention. The “B” figures show simplified diagrams illustrating lengthwise cross-sectional views of the same devices in the “A” figures. Similarly, the “C” figures show simplified diagrams illustrating widthwise cross-sectional views of the same devices in the “A” figures. In some cases, certain features are omitted to highlight other features and the relationships between such features. Those of ordinary skill in the art will recognize variations, modifications, and alternatives to the examples shown in these figure series.

FIGS. 34A-34C (devices 1601 to 1603, respectively) are diagrams illustrating various cross-sectional views of a crystal acoustic resonator device including a plurality of periodically poled piezoelectric layers and methods of forming the same via a transfer process using a sacrificial layer for crystal acoustic resonator devices according to embodiments of the inventive concept. It will be understood that the piezoelectric stacks described as part of the transfer processes herein can be periodically poled piezoelectric layers having alternating ferroelectric polarizations in some embodiments. For example, it will be understood that the piezoelectric stack 1620 shown in FIGS. 34A-34C can represent a periodically poled 5 layer piezoelectric stack as shown, for example, in FIG. 2.

As shown, these figures illustrate the method step of forming a piezoelectric stack 1620 overlying a growth substrate 1610. In an example, the growth substrate 1610 can include silicon(S), silicon carbide (SiC), or other like materials. The piezoelectric stack 1620 can be formed according to any of the embodiments described herein such as the PP-XBAW as shown in FIG. 12, the PP-BAW process as shown in FIG. 14, and the PC-BAW process.

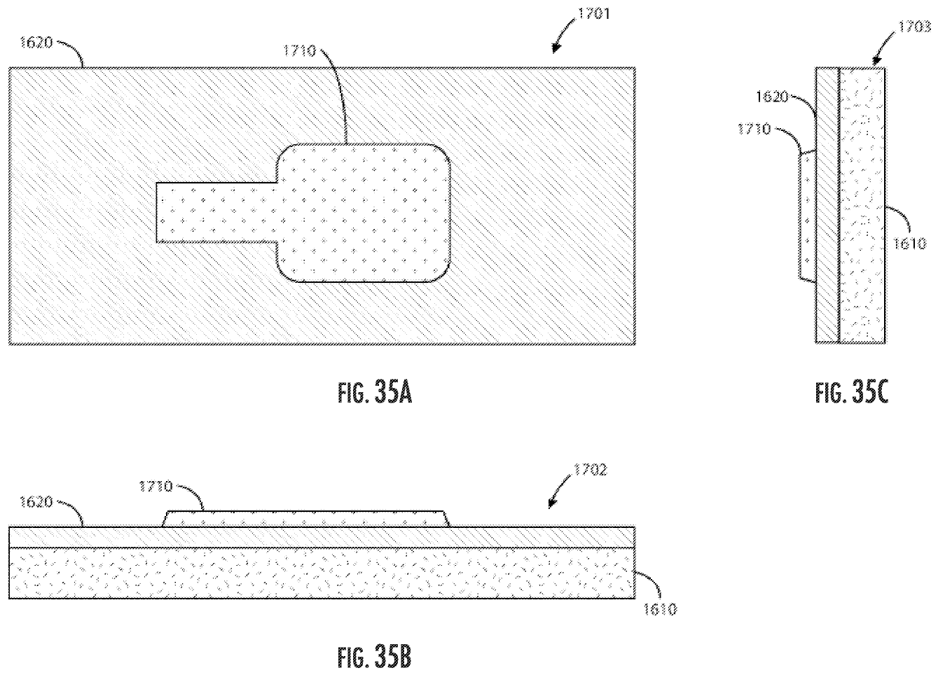

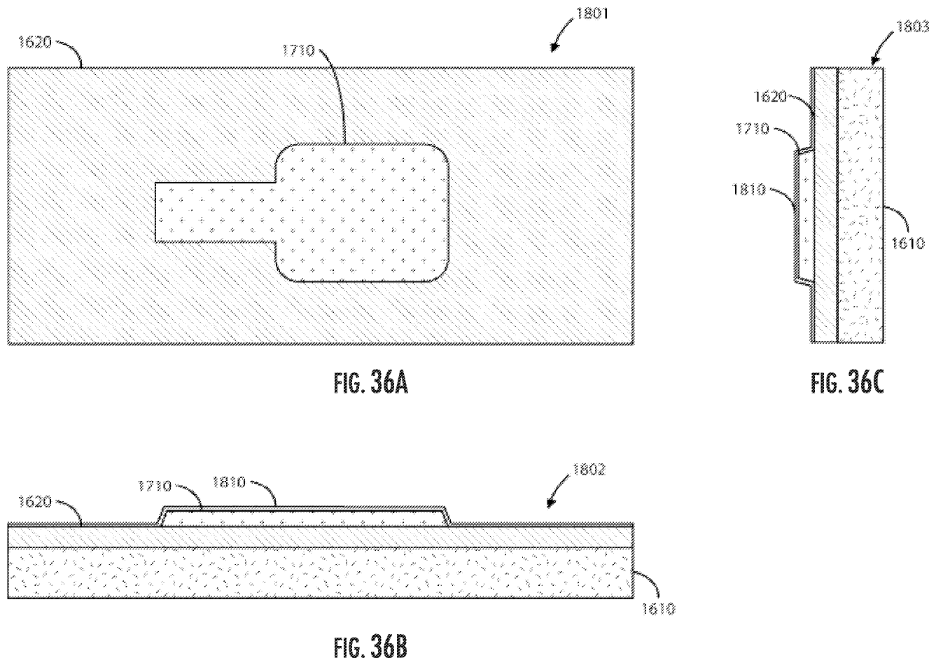

FIGS. 35A-35C (devices 1701 to 1703, respectively) are simplified diagrams illustrating various cross-sectional views of a crystal acoustic resonator device and of method steps for a transfer process using a sacrificial layer for crystal acoustic resonator devices according to an example of the present invention. As shown, these figures illustrate the method step of forming a first electrode 1710 overlying the surface region of the piezoelectric stack 1620. In an example, the first electrode 1710 can include molybdenum (Mo), ruthenium (Ru), tungsten (W), or other like materials. In a specific example, the first electrode 1710 can be subjected to a dry etch with a slope. As an example, the slope can be about 60 degrees.

FIGS. 36A-36C (devices 1801 to 1803, respectively) are diagrams illustrating various cross-sectional views of a crystal acoustic resonator device and of method steps for a transfer process using a sacrificial layer for crystal acoustic resonator devices according to an example of the present invention. As shown, these figures illustrate the method step of forming a first passivation layer 1810 overlying the first electrode 1710 and the piezoelectric stack 1620. In an example, the first passivation layer 1810 can include silicon nitride (SiN), silicon oxide (SiO), or other like materials. In a specific example, the first passivation layer 1810 can have a thickness ranging from about 50 nm to about 100 nm.

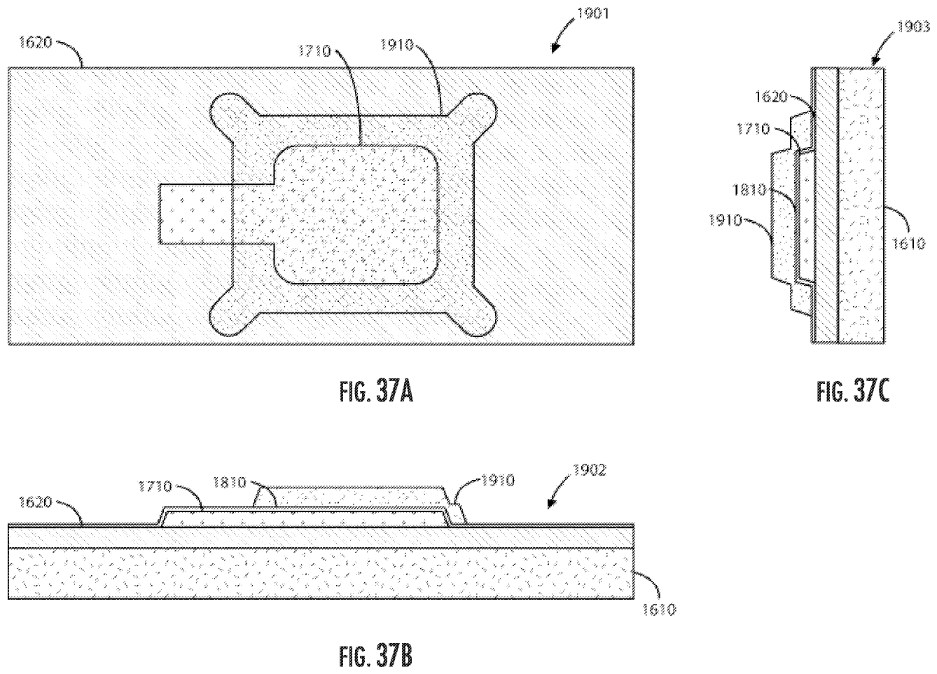

FIGS. 37A-37C (devices 1901 to 1903, respectively) are diagrams illustrating various cross-sectional views of a crystal acoustic resonator device and of method steps for a transfer process using a sacrificial layer for crystal acoustic resonator devices according to an example of the present invention. As shown, these figures illustrate the method step of forming a sacrificial layer 1910 overlying a portion of the first electrode 1810 and a portion of the piezoelectric stack 1620. In an example, the sacrificial layer 1910 can include polycrystalline silicon (poly-Si), amorphous silicon (a-Si), or other like materials. In a specific example, this sacrificial layer 1910 can be subjected to a dry etch with a slope and be deposited with a thickness of about 1 μm. Further, phosphorous doped SiO₂ (PSG) can be used as the sacrificial layer with different combinations of support layer (e.g., SiNx).

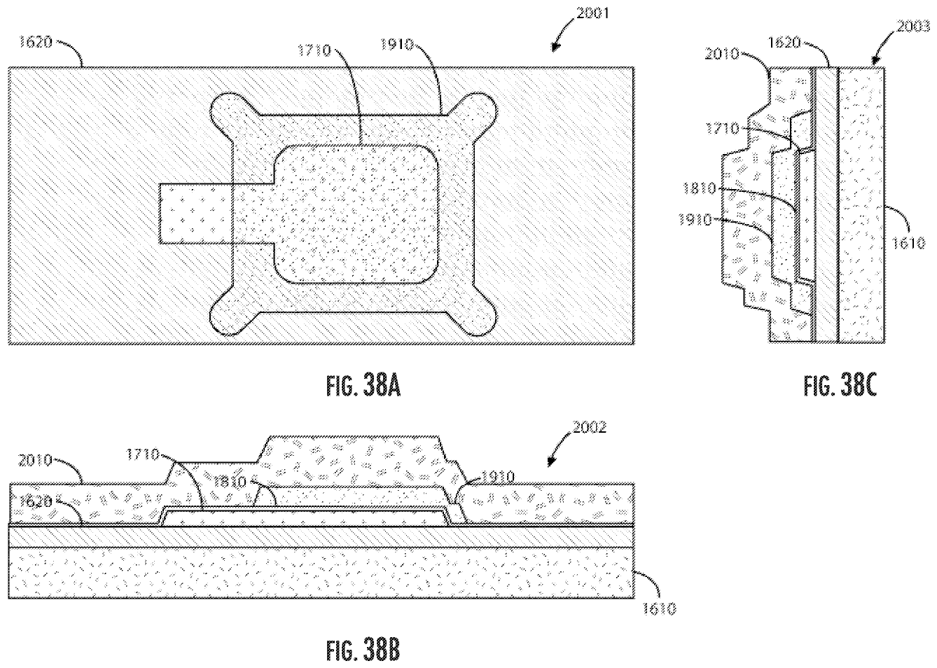

FIGS. 38A-38C (devices 2001 to 2003, respectively) are diagrams illustrating various cross-sectional views of a crystal acoustic resonator device and of method steps for a transfer process using a sacrificial layer for crystal acoustic resonator devices according to an example of the present invention. As shown, these figures illustrate the method step of forming a support layer 2010 overlying the sacrificial layer 1910, the first electrode 1710, and the piezoelectric stack 1620. In an example, the support layer 2010 can include silicon dioxide (SiO₂), silicon nitride (SiN), or other like materials. In a specific example, this support layer 2010 can be deposited with a thickness of about 2-3 μm. As described above, other support layers (e.g., SiNx) can be used in the case of a PSG sacrificial layer.

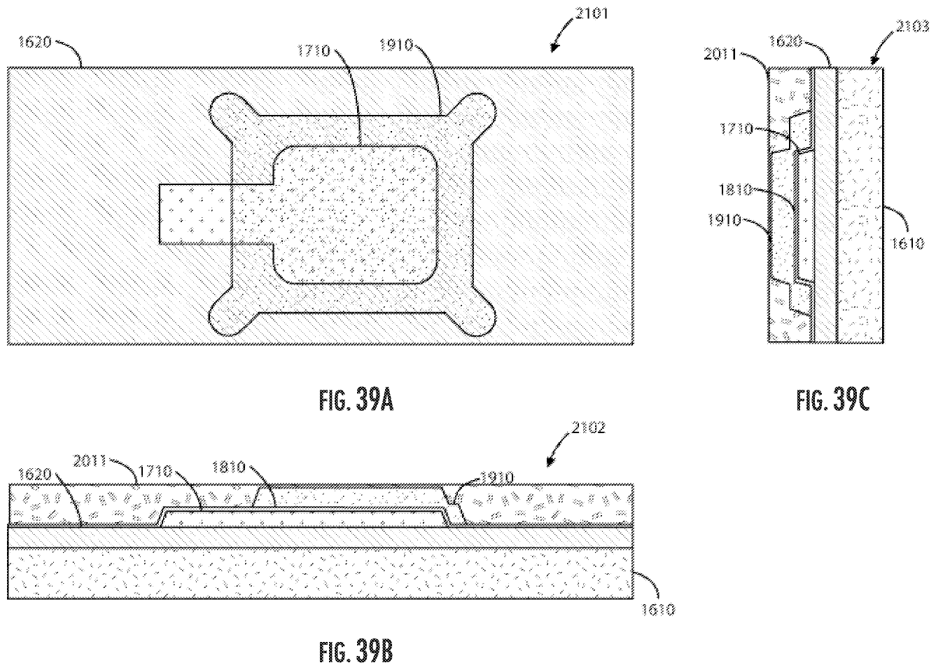

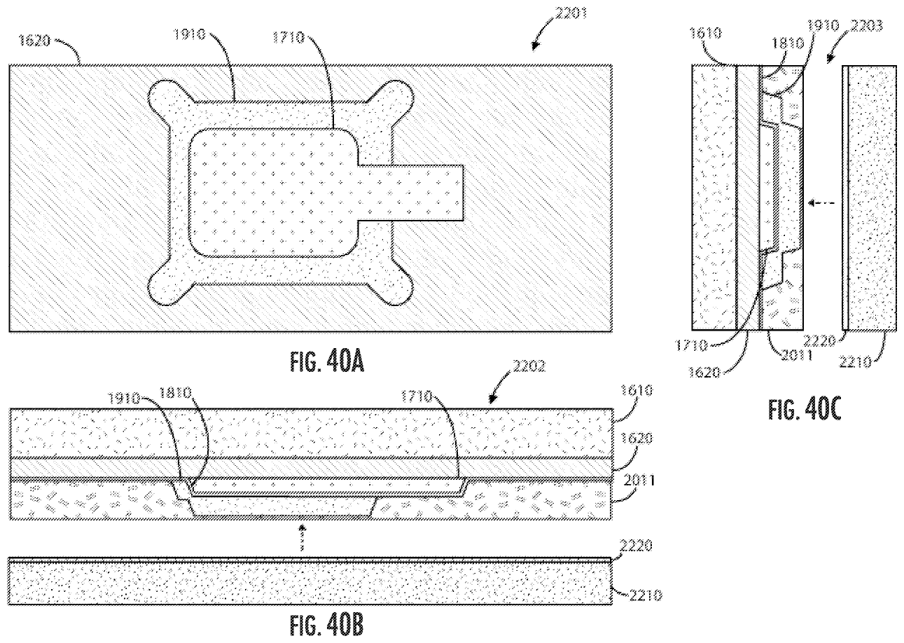

FIGS. 39A-39C (devices 2101 to 2103, respectively) are diagrams illustrating various cross-sectional views of a crystal acoustic resonator device and of method steps for a transfer process using a sacrificial layer for crystal acoustic resonator devices according to an example of the present invention. As shown, these figures illustrate the method step of polishing the support layer 2010 to form a polished support layer 2011. In an example, the polishing process can include a chemical-mechanical planarization process or the like.

FIGS. 40A-40C (devices 2201 to 2203, respectively) are diagrams illustrating various cross-sectional views of a crystal acoustic resonator device and of method steps for a transfer process using a sacrificial layer for crystal acoustic resonator devices according to an example of the present invention. As shown, these figures illustrate flipping the device and physically coupling overlying the support layer 2011 overlying a bond substrate 2210. In an example, the bond substrate 2210 can include a bonding support layer 2220 (SiO₂ or like material) overlying a substrate having silicon (Si), sapphire (Al₂O₃), silicon dioxide (SiO₂), silicon carbide (SiC), or other like materials. In a specific embodiment, the bonding support layer 2220 of the bond substrate 2210 is physically coupled to the polished support layer 2011. Further, the physical coupling process can include a room temperature bonding process following by a 300 degree Celsius annealing process.

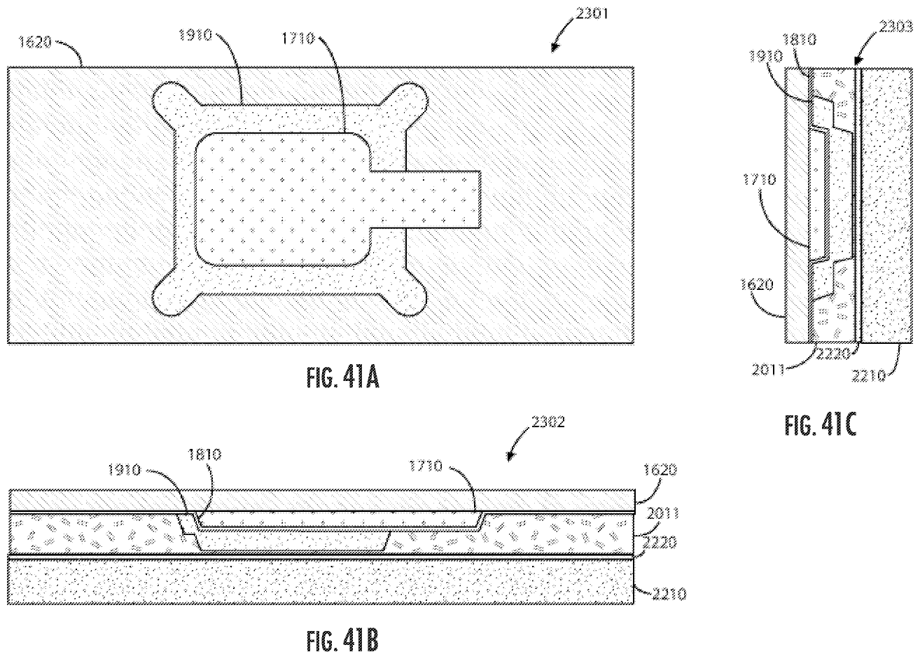

FIGS. 41A-41C (devices 2301 to 2303, respectively) are diagrams illustrating various cross-sectional views of a crystal acoustic resonator device and of method steps for a transfer process using a sacrificial layer for crystal acoustic resonator devices according to an example of the present invention. As shown, these figures illustrate the method step of removing the growth substrate 1610 or otherwise the transfer of the piezoelectric stack 1620. In an example, the removal process can include a grinding process, a blanket etching process, a film transfer process, an ion implantation transfer process, a laser crack transfer process, or the like and combinations thereof.

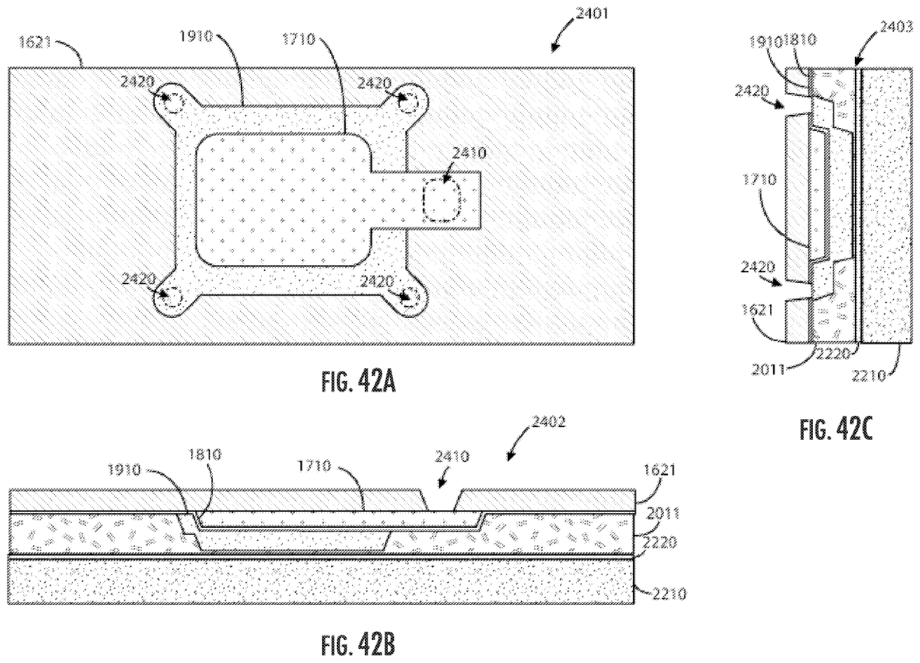

FIGS. 42A-42C (devices 2401 to 2403, respectively) are diagrams illustrating various cross-sectional views of a crystal acoustic resonator device and of method steps for a transfer process using a sacrificial layer for crystal acoustic resonator devices according to an example of the present invention. As shown, these figures illustrate the method step of forming an electrode contact via 2410 within the piezoelectric stack 1620 (becoming piezoelectric stack 1621) overlying the first electrode 1710 and forming one or more release holes 2420 within the piezoelectric stack 1620 and the first passivation layer 1810 overlying the sacrificial layer 1910. The via forming processes can include various types of etching processes.

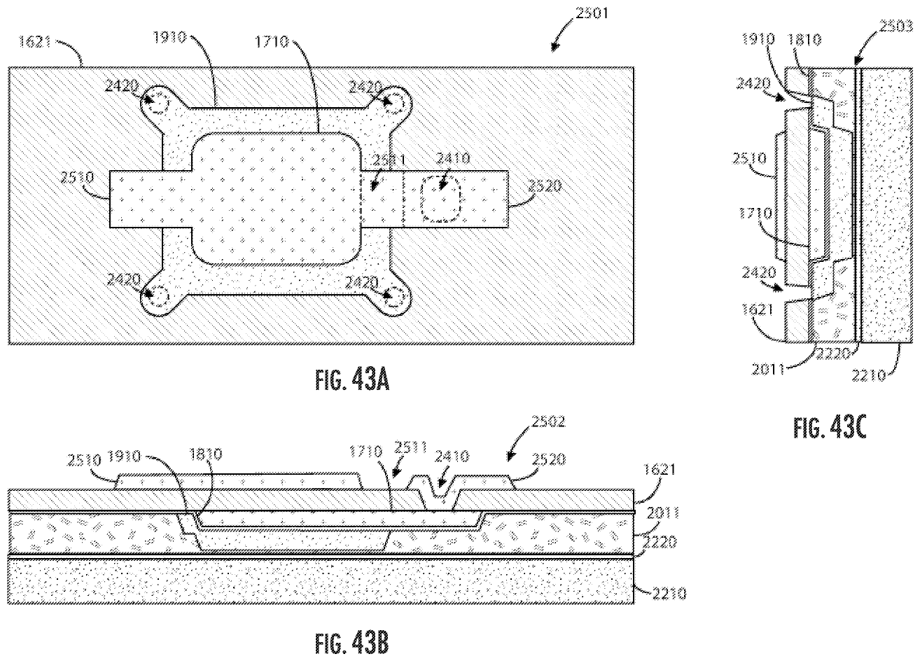

FIGS. 43A-43C (devices 2501 to 2503, respectively) are diagrams illustrating various cross-sectional views of a crystal acoustic resonator device and of method steps for a transfer process using a sacrificial layer for crystal acoustic resonator devices according to an example of the present invention. As shown, these figures illustrate the method step of forming a second electrode 2510 overlying the piezoelectric stack 1621. In an example, the formation of the second electrode 2510 includes depositing molybdenum (Mo), ruthenium (Ru), tungsten (W), or other like materials; and then etching the second electrode 2510 to form an electrode cavity 2511 and to remove portion 2511 from the second electrode to form a top metal 2520. Further, the top metal 2520 is physically coupled to the first electrode 1720 through electrode contact via 2410.

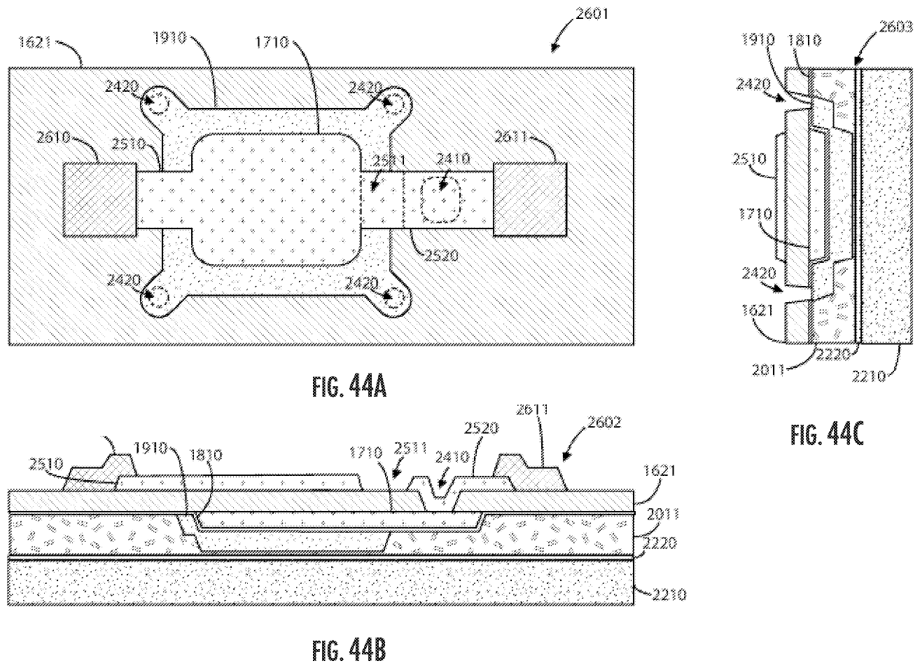

FIGS. 44A-44C (devices 2601 to 2603, respectively) are diagrams illustrating various cross-sectional views of a crystal acoustic resonator device and of method steps for a transfer process using a sacrificial layer for crystal acoustic resonator devices according to an example of the present invention. As shown, these figures illustrate the method step of forming a first contact metal 2610 overlying a portion of the second electrode 2510 and a portion of the piezoelectric stack 1621, and forming a second contact metal 2611 overlying a portion of the top metal 2520 and a portion of the piezoelectric stack 1621. In an example, the first and second contact metals can include gold (Au), aluminum (Al), copper (Cu), nickel (Ni), aluminum bronze (AlCu), or related alloys of these materials or other like materials.

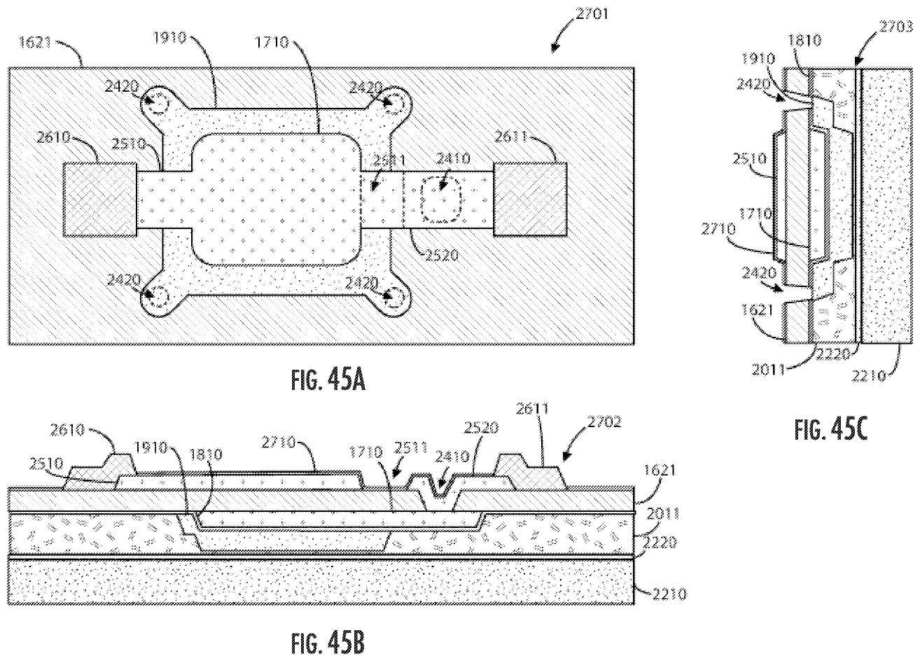

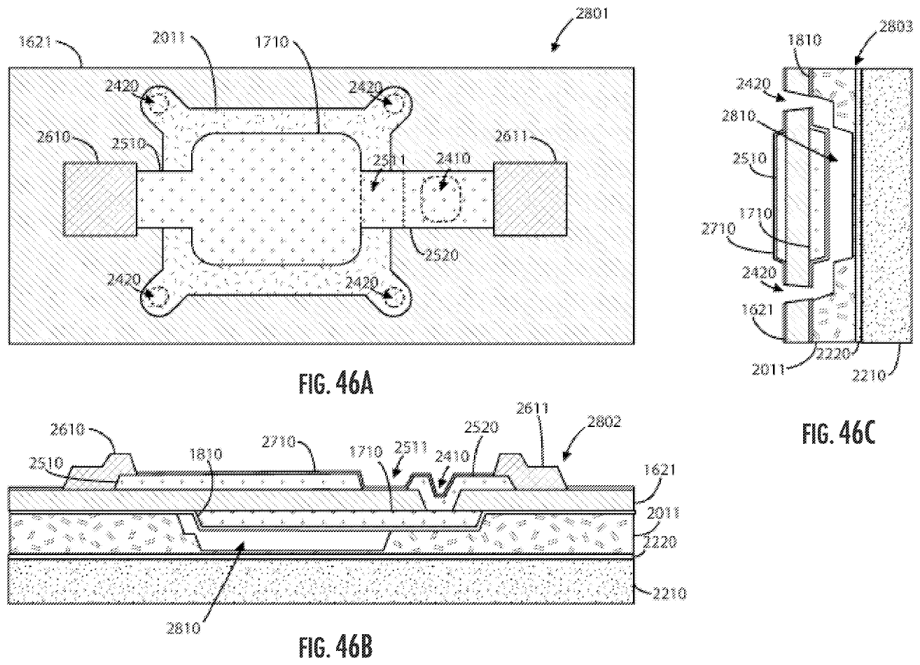

FIGS. 45A-45C (devices 2701 to 2703, respectively) are diagrams illustrating various cross-sectional views of a crystal acoustic resonator device and of method steps for a transfer process using a sacrificial layer for crystal acoustic resonator devices according to an example of the present invention. As shown, these figures illustrate the method step of forming a second passivation layer 2710 overlying the second electrode 2510, the top metal 2520, and the piezoelectric stack 1621. In an example, the second passivation layer 2710 can include silicon nitride (SiN), silicon oxide (SiO), or other like materials. In a specific example, the second passivation layer 2710 can have a thickness ranging from about 50 nm to about 100 nm. FIGS. 46A-46C (devices 2801 to 2803, respectively) are diagrams illustrating various cross-sectional views of a crystal acoustic resonator device and of method steps for a transfer process using a sacrificial layer for crystal acoustic resonator devices according to an example of the present invention. As shown, these figures illustrate the method step of removing the sacrificial layer 1910 to form an air cavity 2810. In an example, the removal process can include a poly-Si etch or an a-Si etch, or the like.

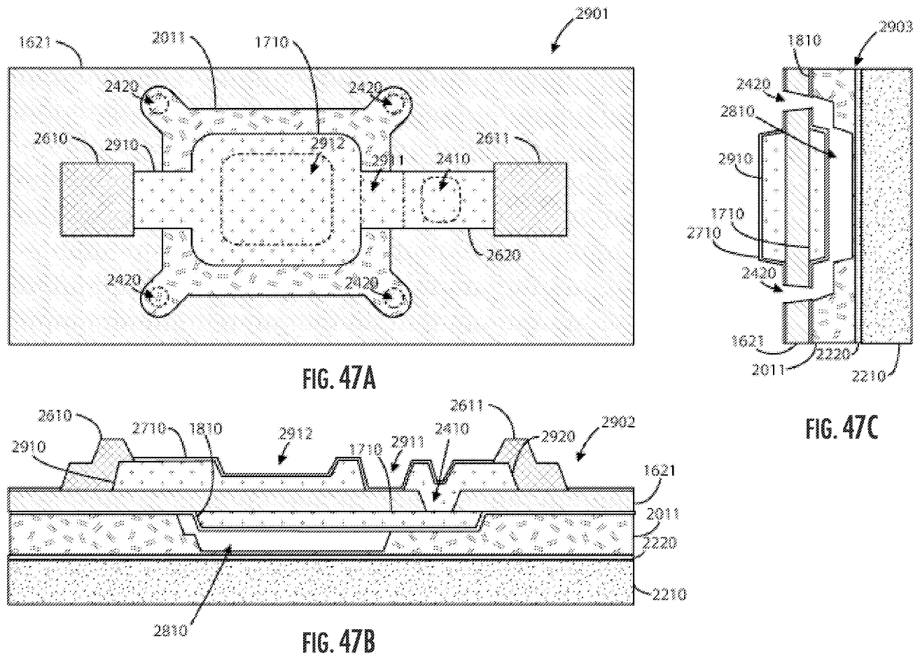

FIGS. 47A-47C (devices 2901 to 2903, respectively) are diagrams illustrating various cross-sectional views of a crystal acoustic resonator device and of method steps for a transfer process using a sacrificial layer for crystal acoustic resonator devices according to another example of the present invention. As shown, these figures illustrate the method step of processing the second electrode 2510 and the top metal 2520 to form a processed second electrode 2910 and a processed top metal 2920. This step can follow the formation of second electrode 2510 and top metal 2520. In an example, the processing of these two components includes depositing molybdenum (Mo), ruthenium (Ru), tungsten (W), or other like materials; and then etching (e.g., dry etch or the like) this material to form the processed second electrode 2910 with an electrode cavity 2912 and the processed top metal 2920. The processed top metal 2920 remains separated from the processed second electrode 2910 by the removal of portion 2911. In a specific example, the processed second electrode 2910 is characterized by the addition of an energy confinement structure configured on the processed second electrode 2910 to increase Q.

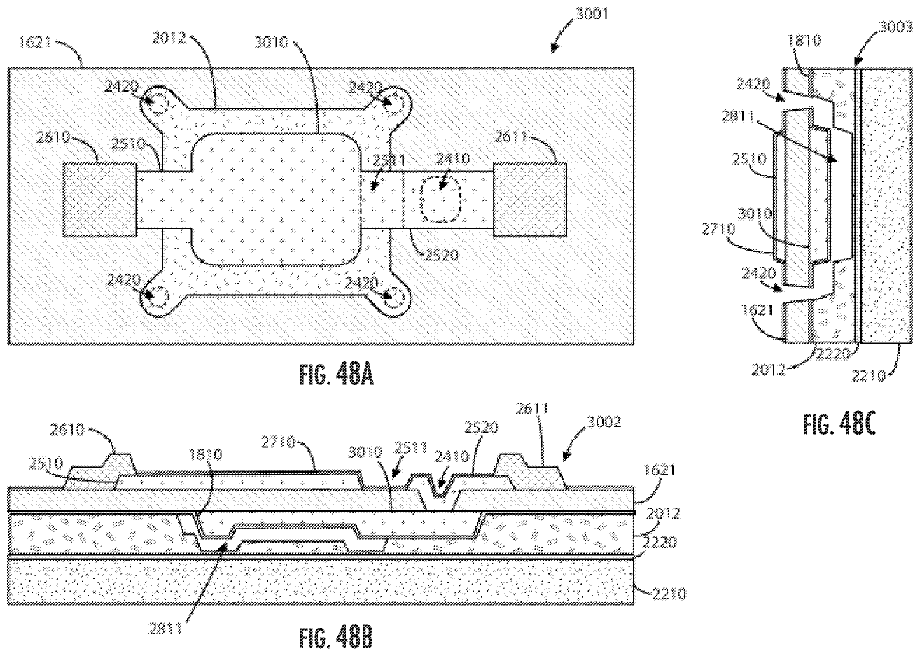

FIGS. 48A-48C (devices 3001 to 3003, respectively) are diagrams illustrating various cross-sectional views of a crystal acoustic resonator device and of method steps for a transfer process using a sacrificial layer for crystal acoustic resonator devices according to another example of the present invention. As shown, these figures illustrate the method step of processing the first electrode 1710 to form a processed first electrode 2310. This step can follow the formation of first electrode 1710. In an example, the processing of these two components includes depositing molybdenum (Mo), ruthenium (Ru), tungsten (W), or other like materials; and then etching (e.g., dry etch or the like) this material to form the processed first electrode 3010 with an electrode cavity, similar to the processed second electrode 2910. Air cavity 2811 shows the change in cavity shape due to the processed first electrode 3010. In a specific example, the processed first electrode 3010 is characterized by the addition of an energy confinement structure configured on the processed second electrode 3010 to increase Q.

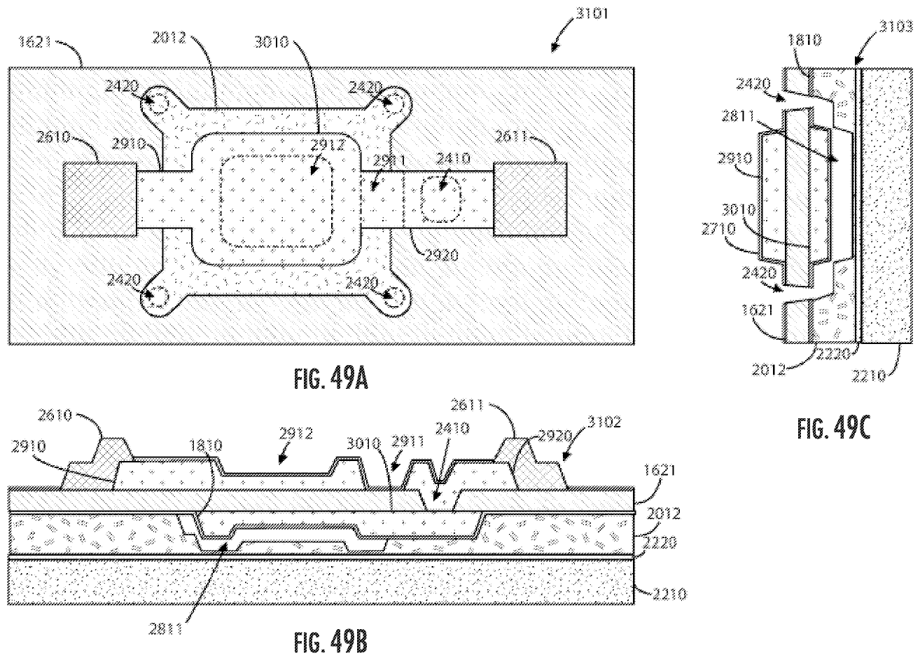

FIGS. 49A-49C (devices 3101 to 3103, respectively) are diagrams illustrating various cross-sectional views of a crystal acoustic resonator device and of method steps for a transfer process using a sacrificial layer for crystal acoustic resonator devices according to another example of the present invention. As shown, these figures illustrate the method step of processing the first electrode 1710, to form a processed first electrode 2310, and the second electrode 2510/top metal 2520 to form a processed second electrode 2910/processed top metal 2920. These steps can follow the formation of each respective electrode, as described for FIGS. 47A-47C and 48A-48C. Those of ordinary skill in the art will recognize other variations, modifications, and alternatives.

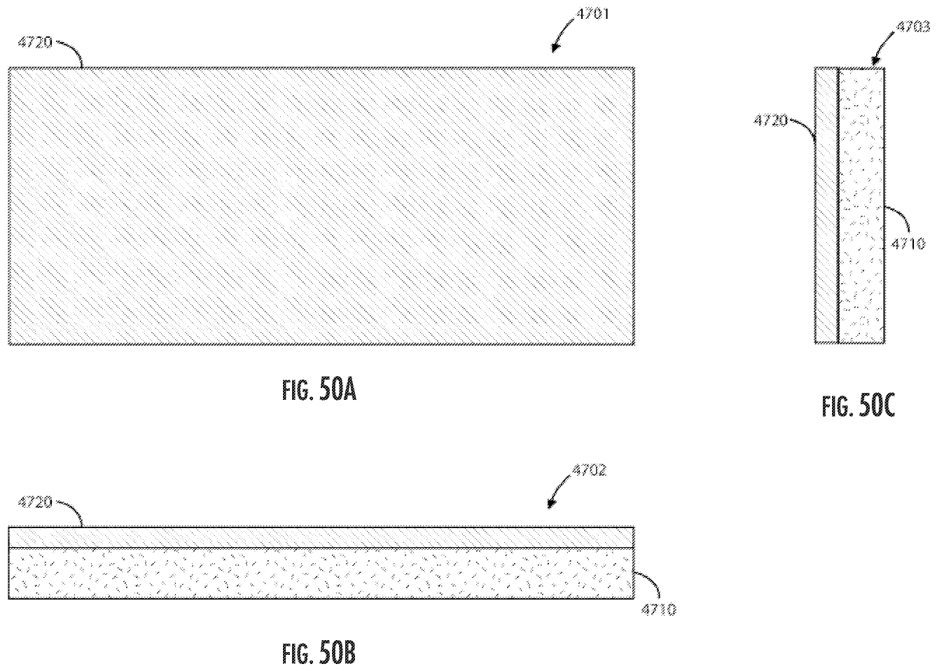

FIGS. 50A-50C through FIGS. 62A-62C illustrate methods of fabricating an acoustic resonator device including a plurality of periodically poled piezoelectric layers, as described herein, using a transfer structure with a multilayer mirror structure. In these figure series described below, the “A” figures show simplified diagrams illustrating top cross-sectional views of crystal resonator devices according to various embodiments of the present invention. The “B” figures show simplified diagrams illustrating lengthwise cross-sectional views of the same devices in the “A” figures. Similarly, the “C” figures show simplified diagrams illustrating widthwise cross-sectional views of the same devices in the “A” figures. In some cases, certain features are omitted to highlight other features and the relationships between such features. Those of ordinary skill in the art will recognize variations, modifications, and alternatives to the examples shown in these figure series.

FIGS. 50A-50C (devices 4701 to 4703, respectively) are diagrams illustrating various cross-sectional views of a crystal acoustic resonator device methods of forming the same using a transfer process with a multilayer mirror for the crystal acoustic resonator devices in some embodiments according to the inventive concept. It will be understood that the piezoelectric stacks described as part of the transfer processes herein can be periodically poled piezoelectric layers having alternating ferroelectric polarizations in some embodiments. For example, it will be understood that the piezoelectric stack 4720 shown in FIGS. 50A-50C can represent a periodically poled 5 layer piezoelectric stack as shown, for example, in FIG. 2.

As shown, these figures illustrate the method step of forming a piezoelectric stack 4720 overlying a growth substrate 4710. In an example, the growth substrate 4710 can include silicon(S), silicon carbide (SiC), or other like materials. The piezoelectric stack 4720 can be formed according to any of the embodiments described herein such as the PP-XBAW as shown in FIG. 12, the PP-BAW process as shown in FIG. 14, and the PC-BAW process.

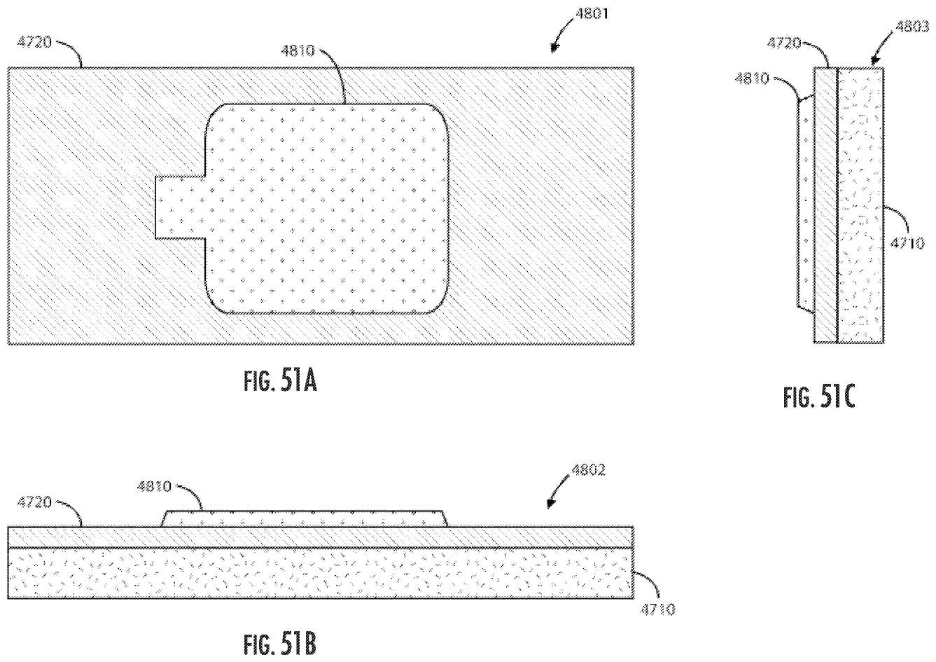

FIGS. 51A-51C (devices 4801 to 4803, respectively) are diagrams illustrating various cross-sectional views of a crystal acoustic resonator device and of method steps for a transfer process with a multilayer mirror for crystal acoustic resonator devices according to an example of the present invention. As shown, these figures illustrate the method step of forming a first electrode 4810 overlying the surface region of the piezoelectric stack 4720. In an example, the first electrode 4810 can include molybdenum (Mo), ruthenium (Ru), tungsten (W), or other like materials. In a specific example, the first electrode 4810 can be subjected to a dry etch with a slope. As an example, the slope can be about 60 degrees.

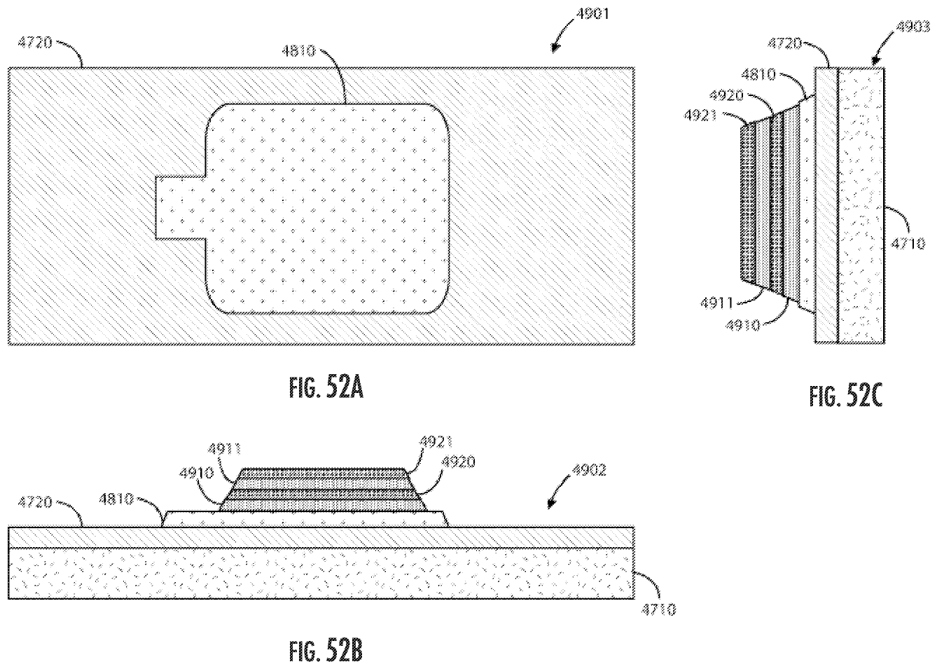

FIGS. 52A-52C (devices 4901 to 4903, respectively) are diagrams illustrating various cross-sectional views of a crystal acoustic resonator device and of method steps for a transfer process with a multilayer mirror for crystal acoustic resonator devices according to an example of the present invention. As shown, these figures illustrate the method step of forming a multilayer mirror or reflector structure. In an example, the multilayer mirror includes at least one pair of layers with a low impedance layer 4910 and a high impedance layer 4920. In FIGS. 52A-52C, two pairs of low/high impedance layers are shown (low: 4910 and 4911; high: 4920 and 4921). In an example, the mirror/reflector area can be larger than the resonator area and can encompass the resonator area. In a specific embodiment, each layer thickness is about ¼ of the wavelength of an acoustic wave at a targeting frequency. The layers can be deposited in sequence and be etched afterwards, or each layer can be deposited and etched individually. In another example, the first electrode 4810 can be patterned after the mirror structure is patterned.

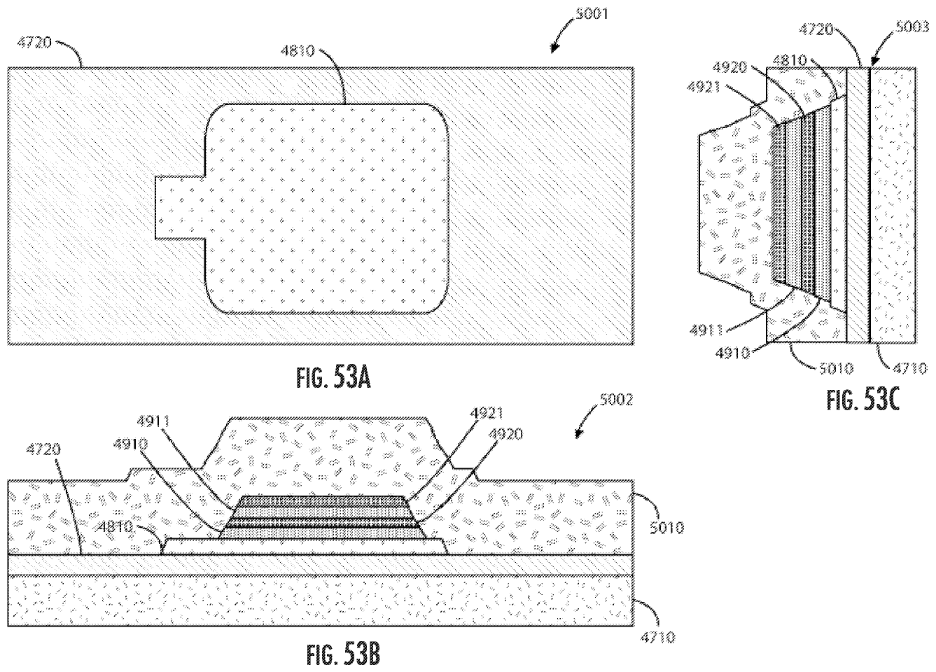

FIGS. 53A-53C (devices 5001 to 5003, respectively) are diagrams illustrating various cross-sectional views of a crystal acoustic resonator device and of method steps for a transfer process with a multilayer mirror for crystal acoustic resonator devices according to an example of the present invention. As shown, these figures illustrate the method step of forming a support layer 5010 overlying the mirror structure (layers 4910, 4911, 4920, and 4921), the first electrode 4810, and the piezoelectric stack 4720. In an example, the support layer 5010 can include silicon dioxide (SiO₂), silicon nitride (SiN), or other like materials. In a specific example, this support layer 5010 can be deposited with a thickness of about 2-3 μm. As described above, other support layers (e.g., SiNx) can be used.

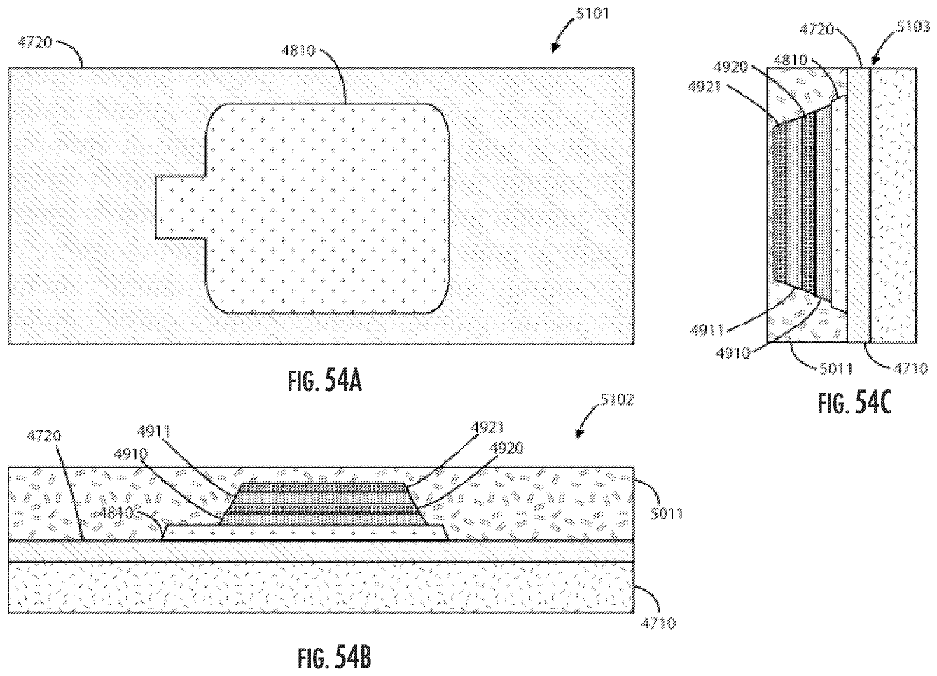

FIGS. 54A-54C (devices 5101 to 5103, respectively) are diagrams illustrating various cross-sectional views of a crystal acoustic resonator device and of method steps for a transfer process with a multilayer mirror for crystal acoustic resonator devices according to an example of the present invention. As shown, these figures illustrate the method step of polishing the support layer 5010 to form a polished support layer 5011. In an example, the polishing process can include a chemical-mechanical planarization process or the like.

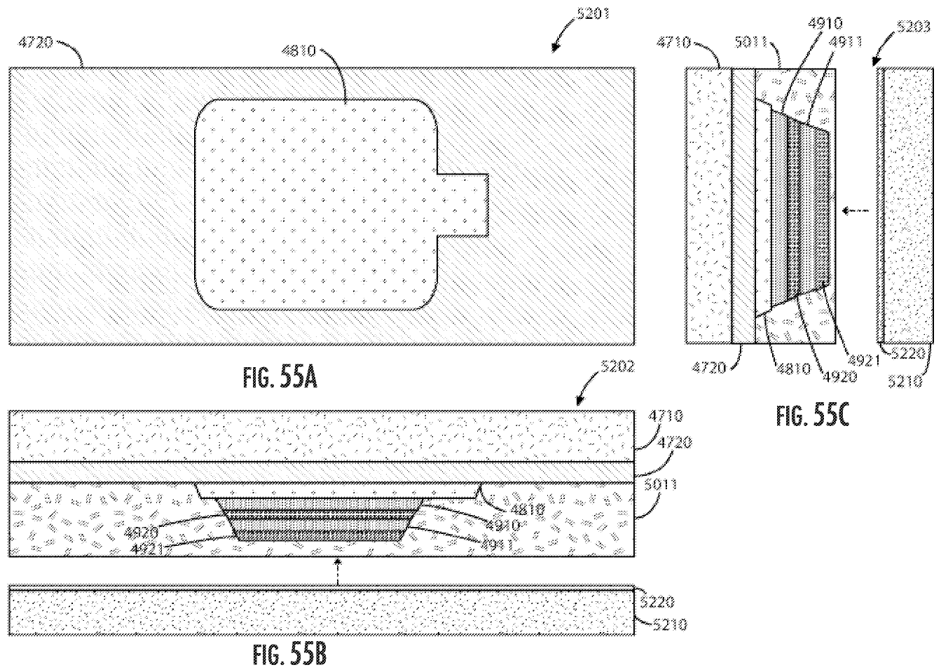

FIGS. 55A-55C (devices 5201 to 5203, respectively) are diagrams illustrating various cross-sectional views of a crystal acoustic resonator device and of method steps for a transfer process with a multilayer mirror for crystal acoustic resonator devices according to an example of the present invention. As shown, these figures illustrate flipping the device and physically coupling overlying the support layer 5011 overlying a bond substrate 5210. In an example, the bond substrate 5210 can include a bonding support layer 5220 (SiO₂ or like material) overlying a substrate having silicon (Si), sapphire (Al₂O₃), silicon dioxide (SiO₂), silicon carbide (SiC), or other like materials. In a specific embodiment, the bonding support layer 5220 of the bond substrate 5210 is physically coupled to the polished support layer 5011. Further, the physical coupling process can include a room temperature bonding process following by a 300 degree Celsius annealing process.

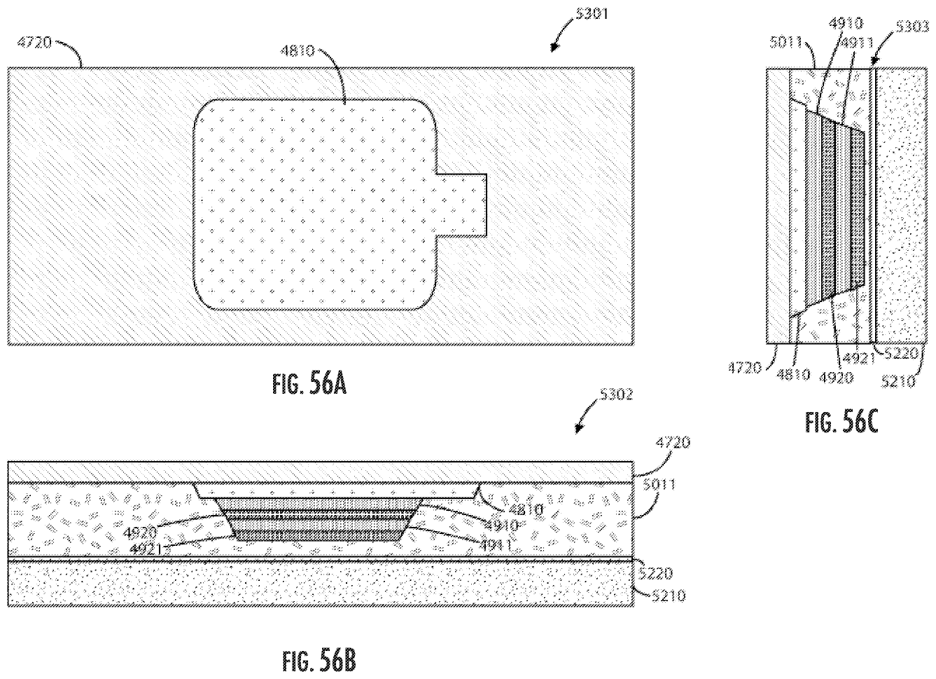

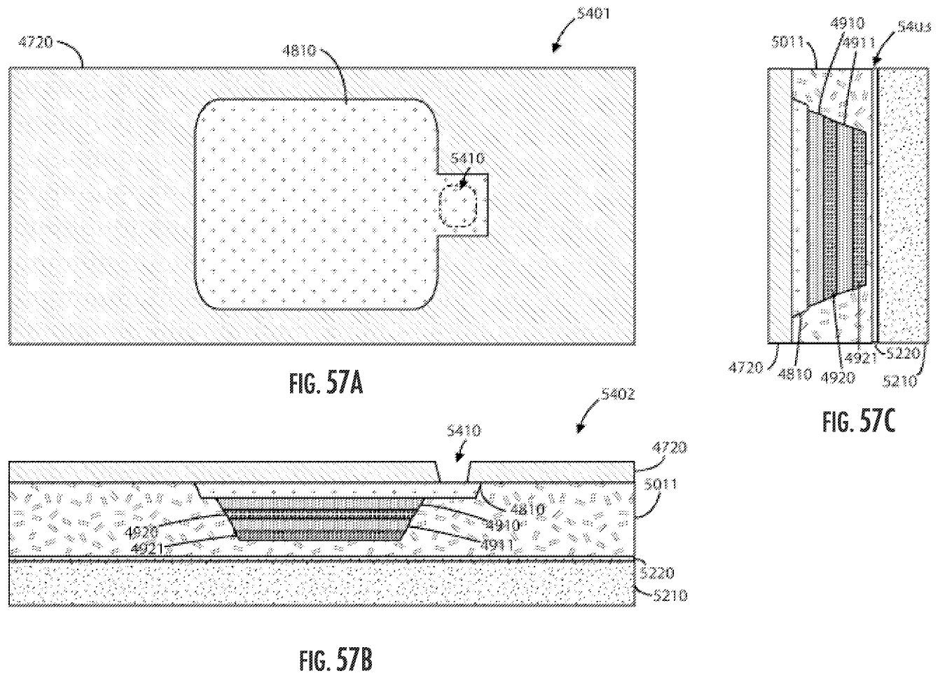

FIGS. 56A-56C (devices 5301 to 5303, respectively) are diagrams illustrating various cross-sectional views of a crystal acoustic resonator device and of method steps for a transfer process with a multilayer mirror for crystal acoustic resonator devices according to an example of the present invention. As shown, these figures illustrate the method step of removing the growth substrate 4710 or otherwise the transfer of the piezoelectric stack 4720. In an example, the removal process can include a grinding process, a blanket etching process, a film transfer process, an ion implantation transfer process, a laser crack transfer process, or the like and combinations thereof.

FIGS. 57A-57C (devices 5401 to 5403, respectively) are diagrams illustrating various cross-sectional views of a crystal acoustic resonator device and of method steps for a transfer process with a multilayer mirror for crystal acoustic resonator devices according to an example of the present invention. As shown, these figures illustrate the method step of forming an electrode contact via 5410 within the piezoelectric stack 4720 overlying the first electrode 4810. The via forming processes can include various types of etching processes.

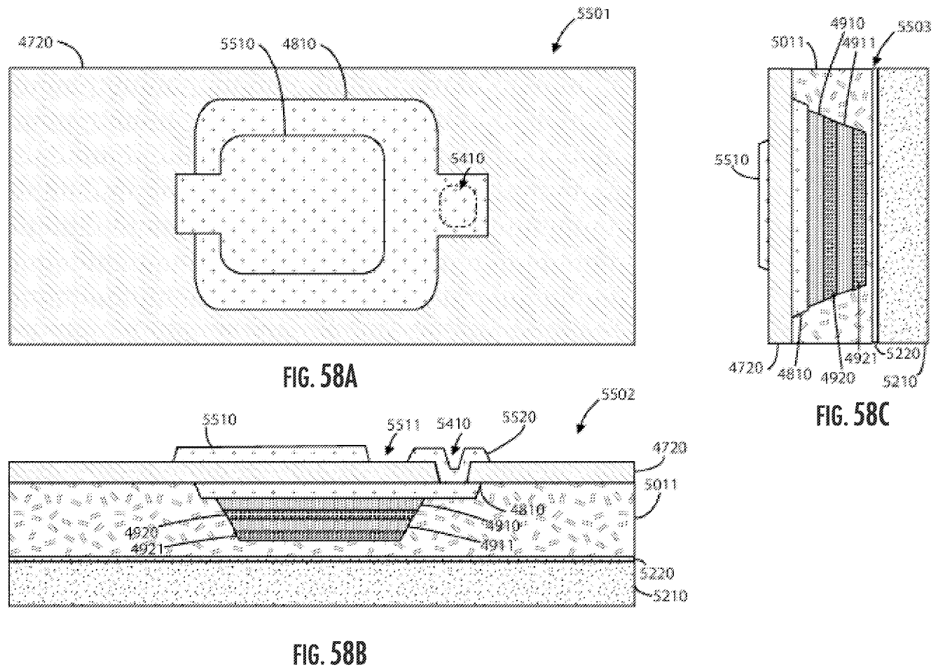

FIGS. 58A-58C (devices 5501 to 5503, respectively) are diagrams illustrating various cross-sectional views of a crystal acoustic resonator device and of method steps for a transfer process with a multilayer mirror for crystal acoustic resonator devices according to an example of the present invention. As shown, these figures illustrate the method step of forming a second electrode 5510 overlying the piezoelectric stack 4720. In an example, the formation of the second electrode 5510 includes depositing molybdenum (Mo), ruthenium (Ru), tungsten (W), or other like materials; and then etching the second electrode 5510 to form an electrode cavity 5511 and to remove portion 5511 from the second electrode to form a top metal 5520. Further, the top metal 5520 is physically coupled to the first electrode 5520 through electrode contact via 5410.

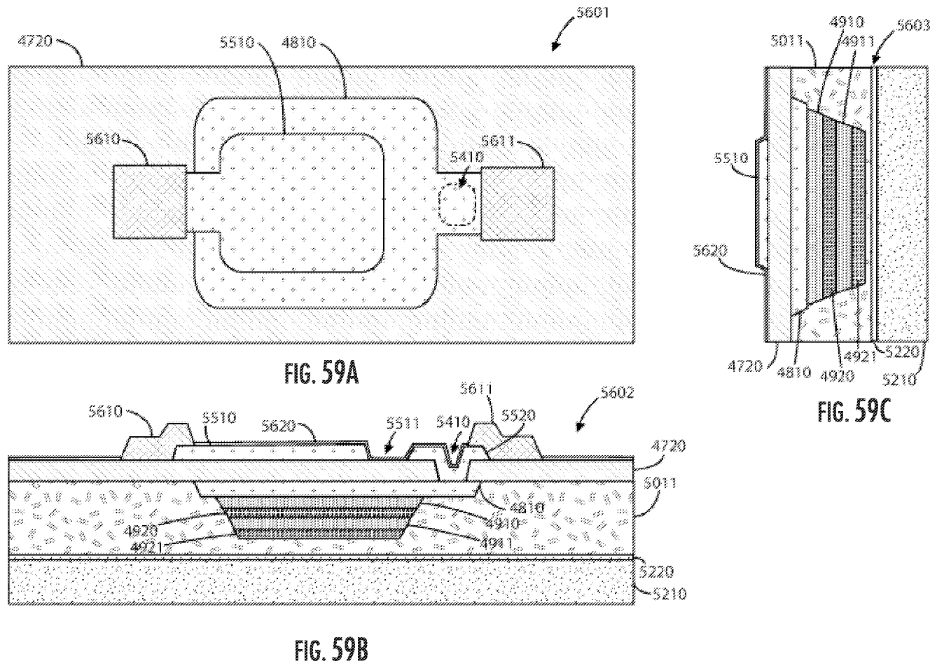

FIGS. 59A-59C (devices 5601 to 5603, respectively) are diagrams illustrating various cross-sectional views of a crystal acoustic resonator device and of method steps for a transfer process with a multilayer mirror for crystal acoustic resonator devices according to an example of the present invention. As shown, these figures illustrate the method step of forming a first contact metal 5610 overlying a portion of the second electrode 5510 and a portion of the piezoelectric stack 4720, and forming a second contact metal 5611 overlying a portion of the top metal 5520 and a portion of the piezoelectric stack 4720. In an example, the first and second contact metals can include gold (Au), aluminum (Al), copper (Cu), nickel (Ni), aluminum bronze (AlCu), or other like materials. This figure also shows the method step of forming a second passivation layer 5620 overlying the second electrode 5510, the top metal 5520, and the piezoelectric stack 4720. In an example, the second passivation layer 5620 can include silicon nitride (SiN), silicon oxide (SiO), or other like materials. In a specific example, the second passivation layer 5620 can have a thickness ranging from about 50 nm to about 100 nm.

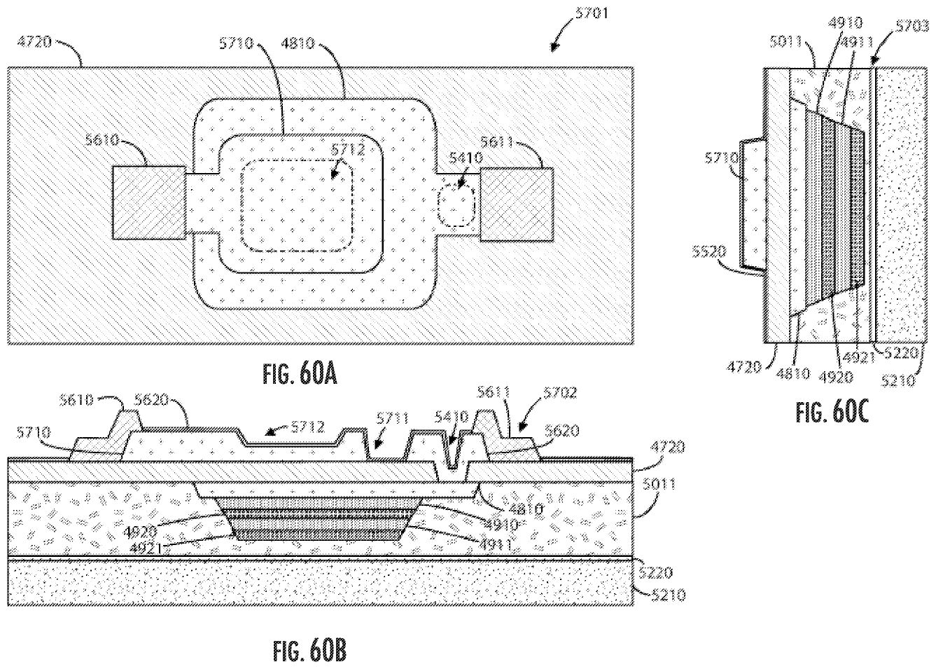

FIGS. 60A-60C (devices 5701 to 5703, respectively) are diagrams illustrating various cross-sectional views of a crystal acoustic resonator device and of method steps for a transfer process with a multilayer mirror for crystal acoustic resonator devices according to another example of the present invention. As shown, these figures illustrate the method step of processing the second electrode 5510 and the top metal 5520 to form a processed second electrode 5710 and a processed top metal 5720. This step can follow the formation of second electrode 5710 and top metal 5720. In an example, the processing of these two components includes depositing molybdenum (Mo), ruthenium (Ru), tungsten (W), or other like materials; and then etching (e.g., dry etch or the like) this material to form the processed second electrode 5410 with an electrode cavity 5712 and the processed top metal 5720. The processed top metal 5720 remains separated from the processed second electrode 5710 by the removal of portion 5711. In a specific example, this processing gives the second electrode and the top metal greater thickness while creating the electrode cavity 5712. In a specific example, the processed second electrode 5710 is characterized by the addition of an energy confinement structure configured on the processed second electrode 5710 to increase Q.

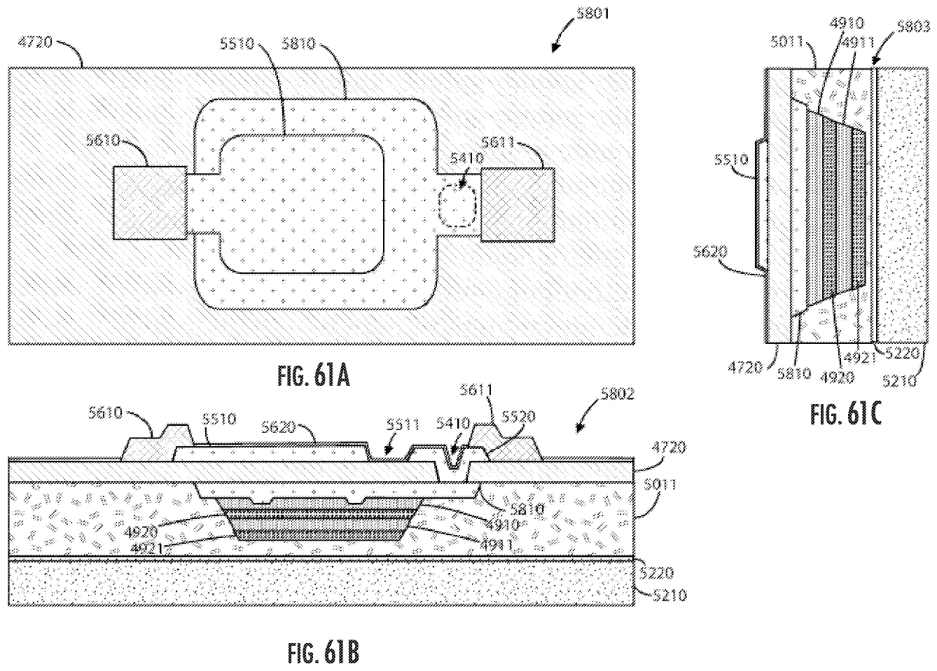

FIGS. 61A-61C (devices 5801 to 5803, respectively) are diagrams illustrating various cross-sectional views of a crystal acoustic resonator device and of method steps for a transfer process with a multilayer mirror for crystal acoustic resonator devices according to another example of the present invention. As shown, these figures illustrate the method step of processing the first electrode 4810 to form a processed first electrode 5810. This step can follow the formation of first electrode 4810. In an example, the processing of these two components includes depositing molybdenum (Mo), ruthenium (Ru), tungsten (W), or other like materials; and then etching (e.g., dry etch or the like) this material to form the processed first electrode 5810 with an electrode cavity, similar to the processed second electrode 5710. Compared to the two previous examples, there is no air cavity. In a specific example, the processed first electrode 5810 is characterized by the addition of an energy confinement structure configured on the processed second electrode 5810 to increase Q.

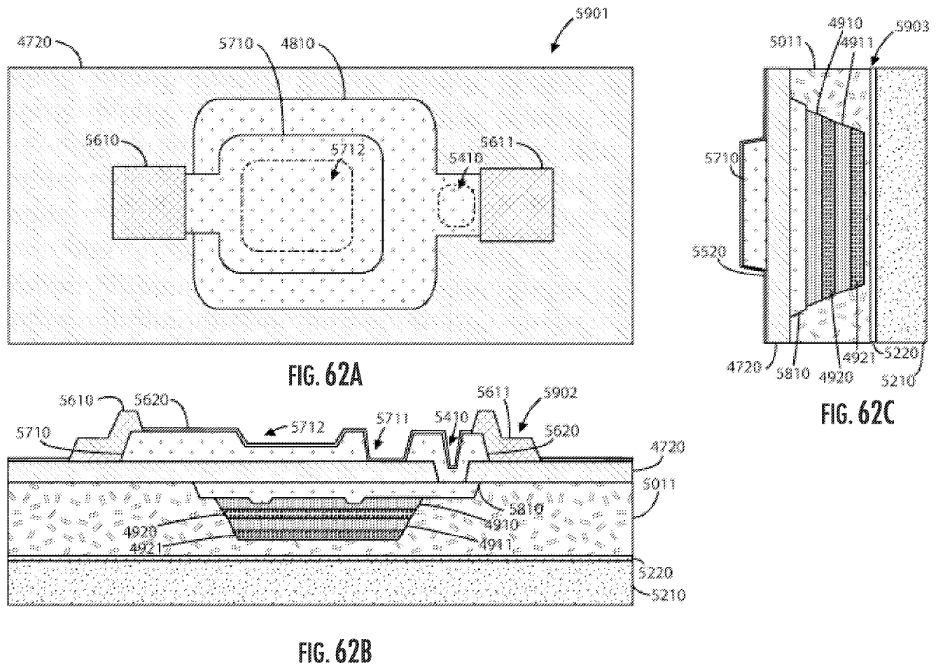

FIGS. 62A-62C (devices 5901 to 5903, respectively) are diagrams illustrating various cross-sectional views of a crystal acoustic resonator device and of method steps for a transfer process with a multilayer mirror for crystal acoustic resonator devices according to another example of the present invention. As shown, these figures illustrate the method step of processing the first electrode 4810, to form a processed first electrode 5810, and the second electrode 5510/top metal 5520 to form a processed second electrode 5710/processed top metal 5720. These steps can follow the formation of each respective electrode, as described for FIGS. 57A-57C and 58A-58C. Those of ordinary skill in the art will recognize other variations, modifications, and alternatives.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise. Additionally, as used herein, the term “and/or” includes any and all combinations of one or more of the associated listed items and may be abbreviated as “/”.

The term “comprise,” as used herein, in addition to its regular meaning, may also include, and, in some embodiments, may specifically refer to the expressions “consist essentially of” and/or “consist of.” Thus, the expression “comprise” can also refer to, in some embodiments, the specifically listed elements of that which is claimed and does not include further elements, as well as embodiments in which the specifically listed elements of that which is claimed may and/or does encompass further elements, or embodiments in which the specifically listed elements of that which is claimed may encompass further elements that do not materially affect the basic and novel characteristic(s) of that which is claimed. For example, that which is claimed, such as a composition, formulation, method, system, etc. “comprising” listed elements also encompasses, for example, a composition, formulation, method, kit, etc. “consisting of,” i.e., wherein that which is claimed does not include further elements, and a composition, formulation, method, kit, etc. “consisting essentially of,” i.e., wherein that which is claimed may include further elements that do not materially affect the basic and novel characteristic(s) of that which is claimed.

The term “about” generally refers to a range of numeric values that one of skill in the art would consider equivalent to the recited numeric value or having the same function or result. For example, “about” may refer to a range that is within ±1%, ±2%, ±5%, ±7%, ±10%, ±15%, or even ±20% of the indicated value, depending upon the numeric values that one of skill in the art would consider equivalent to the recited numeric value or having the same function or result. Furthermore, in some embodiments, a numeric value modified by the term “about” may also include a numeric value that is “exactly” the recited numeric value. In addition, any numeric value presented without modification will be appreciated to include numeric values “about” the recited numeric value, as well as include “exactly” the recited numeric value. Similarly, the term “substantially” means largely, but not wholly, the same form, manner or degree and the particular element will have a range of configurations as a person of ordinary skill in the art would consider as having the same function or result. When a particular element is expressed as an approximation by use of the term “substantially,” it will be understood that the particular element forms another embodiment.

Many different embodiments have been disclosed herein, in connection with the above description and the drawings. It will be understood that it would be unduly repetitious and obfuscating to literally describe and illustrate every combination and subcombination of these embodiments. Accordingly, all embodiments can be combined in any way and/or combination, and the present specification, including the drawings, shall support claims to any such combination or subcombination.

1. A method of forming a piezoelectric resonator device, the method comprising:
forming a first material, including metal and nitrogen atoms, using a first process to provide a first piezoelectric layer having the metal and the nitrogen atoms arranged in a first polar orientation, to establish a first polarization for the first piezoelectric layer; and
forming a second material, including the metal and the nitrogen atoms on the first piezoelectric layer, using a second process to provide a second piezoelectric layer having the metal and the nitrogen atoms arranged in a second polar orientation, to establish a second polarization for the second piezoelectric layer that is opposite of the first polarization.

2. The method of claim 1 wherein:
forming the first material using the first process comprises epitaxially forming the first material first process; and
forming the second material using the second process comprises sputter depositing the second material.

3. The method of claim 1 wherein:
forming the first material using the first process comprises sputter depositing the first material first process; and
forming the second material using the second process comprises epitaxially forming the second material.

4. The method of claim 2 further comprising:
after sputtering the second material onto the first piezoelectric layer to provide the second piezoelectric layer, epitaxially forming a third material, including the metal and the nitrogen atoms on the second piezoelectric layer, the metal and the nitrogen atoms arranged in the first polar orientation to form a third piezoelectric layer having the first polarization.

5. The method of claim 2 further comprising:
after forming the second piezoelectric layer, epitaxially forming a third material, including the metal and the nitrogen atoms on the second piezoelectric layer, the metal and the nitrogen atoms arranged in the first polar orientation to form a third piezoelectric layer having the first polarization; and
sputtering a fourth material, including the metal and the nitrogen atoms, on the third piezoelectric layer, the metal and the nitrogen atoms arranged in the second polar orientation to form a fourth piezoelectric layer having the second polarization.

6. The method of claim 5 further comprising:
after forming the fourth piezoelectric layer, epitaxially forming a fifth material, including the metal and the nitrogen atoms on the fourth piezoelectric layer, the metal and the nitrogen atoms having the first polar orientation on the fourth piezoelectric layer to form a fifth piezoelectric layer having the first polarization.

7. The method of claim 2 further comprising:
before sputtering the second material onto the first piezoelectric layer, exposing a surface of the first piezoelectric layer to an ambient environment to terminate the first polar orientation at the surface of the first piezoelectric layer; and
sputtering the second material including the metal and the nitrogen on the first piezoelectric layer.

8. The method of claim 2 wherein the piezoelectric resonator device is included in a filter device configured to have a center frequency of about f:
wherein epitaxially forming the first material comprises epitaxially forming the first piezoelectric layer to have a thickness of about ½ of 1/f; and
wherein sputtering the second material comprises sputtering the second piezoelectric layer to have a thickness of about ½ of 1/f.

9. The method of claim 2 wherein the piezoelectric resonator device is included in a filter device having a total of 2 piezoelectric layers and the filter device is configured to have a center frequency of about 8 GHz:
wherein the first piezoelectric layer has a thickness of about 525 nm; and
wherein the second piezoelectric layer has a thickness of about 525 nm.

10. The method of claim 4 wherein the piezoelectric resonator device is included in a filter device having a total of 3 piezoelectric layers and the filter device is configured to have a center frequency of about 12 GHz:
wherein the first piezoelectric layer has a thickness of about 350 nm;
wherein the second piezoelectric layer has a thickness of about 350 nm; and
wherein the third piezoelectric layer has a thickness of about 350 nm.

11. The method of claim 6 wherein the piezoelectric resonator device is included in a filter device having a total of 5 piezoelectric layers and the filter device is configured to have a center frequency of about 18 GHz:
wherein the first piezoelectric layer has a thickness of about 232 nm;
wherein the second piezoelectric layer has a thickness of about 232 nm;
wherein the third piezoelectric layer has a thickness of about 232 nm;
wherein the fourth piezoelectric layer has a thickness of about 232 nm; and
wherein the fifth piezoelectric layer has a thickness of about 232 nm.

12. The method of claim 2 wherein epitaxially forming comprises CVD, MOCVD, ALD or MBE.

13. The method of claim 2 wherein epitaxially forming the first material, including a metal and nitrogen, comprises epitaxially forming Al and N.

14. The method of claim 13 wherein sputtering the second material including the metal and the nitrogen comprises sputtering Al and N.

15. The method of claim 2 wherein epitaxially forming the first material, including a metal and nitrogen, comprises epitaxially forming Al, Sc, and N.

16. The method of claim 15 wherein sputtering the second material including the metal and the nitrogen comprises sputtering Al, Sc, and N.

17. The method of claim 2 wherein epitaxially forming the first material comprises epitaxially forming the first material on a substrate comprising a Si substrate, a SiC substrate or a Al₂O₃ substrate.

18. The method of claim 17 wherein the first and second piezoelectric layers comprise a piezoelectric thin film and wherein the substrate comprises a growth substrate, the method further comprising:
forming a first electrode on a first surface of the piezoelectric thin film;
forming a support layer on the first electrode;
attaching a bond substrate to the support layer;
processing the growth substrate while the bond substrate is attached to the support layer to expose a second surface of the piezoelectric thin film that is opposite the first surface of the piezoelectric thin film; and
forming a second electrode on the second surface of the piezoelectric thin film so that the piezoelectric thin film is sandwiched between the first and second electrodes.

19. The method of claim 17 wherein forming the first electrode on the first surface of the piezoelectric thin film is followed by forming a sacrificial layer on the first electrode, wherein the method further comprises:
removing the sacrificial layer after forming the second electrode to form a cavity in the support layer between the second electrode and the bond substrate.

20. A method of forming a piezoelectric resonator device, the method comprising:
forming a first material, including metal and nitrogen atoms, to provide a first piezoelectric layer having the metal and the nitrogen arranged in a first polar orientation, in-situ, for the first piezoelectric layer to establish a first polarization for the first piezoelectric layer; and
a second material including the metal and the nitrogen atoms on the first piezoelectric layer to provide a second piezoelectric layer having the metal and the nitrogen atoms arranged in a second polar orientation, in-situ, to establish a second polarization for the second piezoelectric layer that is opposite to the first polarization.
